(19) United States
(12) Patent Application Publication
(10) Pub. No.: US 2026/0369341 A1
(43) Pub. Date: Nov. 19, 2026

(54) MEMORY CONTROLLER AND OPERATING METHOD OF MEMORY SYSTEM INCLUDING THE SAME

(71) Applicant: SK hynix Inc., Icheon-si (KR)

(72) Inventors: Hyeongshin YOON, San Jose, CA (US); Jaesung YOO, San Jose, CA (US); Hoiju CHUNG, San Jose, CA (US); Seungmin BAEK, San Jose, CA (US); Euisang OH, San Jose, CA (US)

(21) Appl. No.: 19/568,482

(22) Filed: Mar. 16, 2026

Related U.S. Application Data
(63) Continuation-in-part of application No. 19/422,422, filed on Dec. 16, 2025.
(60) Provisional application No. 63/807,211, filed on May 16, 2025.

(51) Int. Cl. G11C 29/52; G11C 29/00; G11C 29/02

(52) U.S. Cl. CPC G11C 29/52; G11C 29/022; G11C 29/76

(57) ABSTRACT

An operating method of a controller includes performing a second scrub operation on one or more adjacent rows specified within a fault boundary based on a faulty row corresponding to a faulty address stored in a non-volatile memory during a power-up sequence operation; and after the power-up sequence operation, storing an address of a target row in the non-volatile memory according to a result of performing a first scrub operation on the target row among a plurality of rows of a memory device.

### CROSS-REFERENCE TO RELATED APPLICATION

The present application is a Continuation-In-Part of application, of U.S. patent application Ser. No. 19/422,422, filed on Dec. 16, 2025, and claims priority under 35 U.S.C. § 119(a) to U.S. Provisional Application No. 63/807,211 filed on May 16, 2025, which are incorporated herein by reference in their entirety

### BACKGROUND

### 1. Field

Various embodiments of the present disclosure relate to a semiconductor design technology, and more particularly, to a memory system for performing a scrub operation.

### 2. Description of the Related Art

A memory system may periodically perform an error check and scrub (ECS) operation (hereinafter referred to as a “scrub operation”), in which data is read from each memory region of a memory device, errors in the read data are checked and corrected, and the corrected data are written back to the corresponding memory region. The memory system may perform an error logging operation to record error logging information obtained as a result of the scrub operation. Based on the error logging information, the memory system may detect errors that have a potential to develop into uncorrectable errors (UEs), thereby providing an optimized reliability, availability, and serviceability (RAS) operation.

If the accuracy of the error logging information of the memory device obtained from the scrub operation is degraded, additional system interrupts may occur even after performing the RAS operation, which may cause a reduction in system stability. Accordingly, various methods are being studied to improve the accuracy of the scrub operation.

### SUMMARY

Embodiments of the present disclosure are directed to a memory controller and a memory system capable of performing an adaptive scrub operation.

In accordance with an embodiment of the present disclosure, an operating method of a controller includes performing a second scrub operation on one or more adjacent rows specified within a fault boundary based on a faulty row corresponding to a faulty address stored in a non-volatile memory during a power-up sequence operation; and after the power-up sequence operation, storing an address of a target row in the non-volatile memory according to a result of performing a first scrub operation on the target row among a plurality of rows of a memory device.

In accordance with an embodiment of the present disclosure, an operating method of a controller includes determining whether a target row among a plurality of rows of a memory device is a faulty row according to a result of performing a first scrub operation on the target row; receiving a scheduled power-down request from a host; and in response to the scheduled power-down request, performing a second scrub operation on one or more adjacent rows specified within a fault boundary based on the faulty row.

According to embodiments of the present disclosure, the memory system may accurately identify fault types by performing an additional designated scrub operation on adjacent rows specified within a fault boundary, based on faulty rows detected by a demand scrub operation or a patrol scrub operation.

According to embodiments of the present disclosure, the memory system may provide an optimized RAS operation by detecting errors that may develop into uncorrectable errors (UEs) that were not detected by conventional methods.

Furthermore, According to embodiments of the present disclosure, the memory system may improve system stability by preventing additional system interrupts.

These and other features and advantages of the embodiments of the present disclosure will become apparent to those skilled in the art from the following detailed description in conjunction with the following drawings.

### BRIEF DESCRIPTION OF THE DRAWINGS

FIG. 1 is a block diagram illustrating a memory system according to an embodiment of the present disclosure.

FIG. 2 is a detailed block diagram illustrating a portion of a memory controller shown in FIG. 1.

FIGS. 3A and 3B are diagrams illustrating a memory cell array of FIG. 1.

FIGS. 4A to 4E are diagrams illustrating fault types that may occur within a fault boundary according to an embodiment of the present disclosure.

FIG. 5 is a flowchart for describing an adaptive scrub operation according to an embodiment of the present disclosure.

FIG. 6 is a flowchart for describing a demand scrub operation according to an embodiment of the present disclosure.

FIG. 7 is a flowchart for describing a patrol scrub operation according to an embodiment of the present disclosure.

FIGS. 8 and 9 are flowcharts for describing a designated scrub operation according to embodiments of the present disclosure.

FIG. 10 is a block diagram illustrating a memory system including a memory module according to an embodiment of the present disclosure.

FIG. 11 is a block diagram illustrating a memory system including a stacked memory device according to an embodiment of the present disclosure.

FIG. 12 is a block diagram illustrating a mobile system including a memory device according to an embodiment of the present disclosure.

FIG. 13 is a flowchart for describing an adaptive scrub operation according to another embodiment of the present disclosure.

FIG. 14 is a flowchart for describing a designated scrub operation of FIG. 13 in more detail.

FIG. 15 is a flowchart for describing a demand scrub operation of FIG. 13 in more detail.

FIG. 16 is a flowchart for describing an adaptive scrub operation according to another embodiment of the present disclosure.

FIG. 17 is a flowchart for describing a designated scrub operation of FIG. 16 in more detail.

### DETAILED DESCRIPTION

Various embodiments of the present disclosure will be described below in more detail with reference to the accompanying drawings. The embodiments of the present disclosure may, however, be in different forms and should not be construed as limited to the embodiments set forth herein. Rather, these embodiments are provided so that this disclosure will be thorough and complete, and will fully convey the scope of the present disclosure to those skilled in the art. Throughout this disclosure, like reference numerals refer to like parts throughout the various figures and embodiments of the present disclosure.

It will be understood that when an element is referred to as being “coupled” or “connected” to another element, it may mean that the two are directly coupled or the two are electrically connected to each other with another circuit or element intervening therebetween. It will be further understood that the terms “comprise”, “include”, “have”, etc. when used in this specification, specify the presence of stated features, numbers, steps, operations, elements, components, and/or combinations of them but do not preclude the presence or addition of one or more other features, numbers, steps, operations, elements, components, and/or combinations thereof. In the present disclosure, the singular forms are intended to include the plural forms as well, unless the context clearly indicates otherwise.

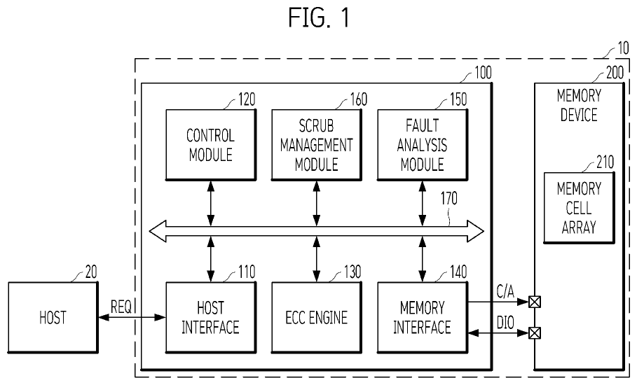

FIG. 1 is a block diagram illustrating a memory system according to an embodiment of the present disclosure.

Referring to FIG. 1, a memory system 10 may include a memory controller 100 and a memory device 200. The memory system 10 may store data under the control of a host 20, such as a cellular phone, a smartphone, an MP3 player, a laptop computer, a desktop computer, a game player, a TV, a tablet PC, or an in-vehicle infotainment system. The host 20 may be an external device of the memory system 10.

The memory controller 100 may control operations of the memory system 10 and control data transfer between the host 20 and the memory device 200. The memory controller 100 may generate a command/address signal C/A according to a request REQ from the host 20 and provide the generated command/address signal C/A to the memory device 200. The memory controller 100 may provide data DIO corresponding to the request REQ from the host 20 to the memory device 200, and provide the data DIO read from the memory device 200 to the host 20. For example, the memory controller 100 may provide a write command, address, and data to the memory device 200 during a write operation. During a read operation, the memory controller 100 may provide a read command and address to the memory device 200 and provide data read from the memory device 200 to the host 20.

The memory device 200 may store the data DIO. The memory device 200 may operate under the control of the memory controller 100. The memory device 200 may include a memory cell array 210 including a plurality of memory cells that store data. The memory device 200 may include dynamic random access memory (DRAM) including dynamic memory cells. In an embodiment, the memory device 200 may be a double data rate synchronous dynamic random access memory (DDR SDRAM), a low power double data rate (LPDDR) type SDRAM, a graphics double data rate (GDDR) SDRAM, a Rambus dynamic random access memory (RDRAM), or others. According to an embodiment, the memory device 200 may include an on-die error correction code (ECC) engine.

The memory device 200 is configured to receive the command/address signal C/A from the memory controller 100 to access an area selected from the memory cell array 210. That is, the memory device 200 may perform an operation instructed by a command on the area selected by an address. For example, the memory device 200 may perform a write operation (e.g., program operation) to write data DIO to the area selected by the address. During a read operation, the memory device 200 may read data DIO from the area selected by the address.

The memory controller 100 may include a host interface 110, a control module 120, an error correction code (ECC) engine 130, a memory interface 140, a fault analysis module 150, a scrub management module 160, and a bus 170.

The host interface 110 may be an interface for communication between the host 20 and the memory controller 100. The host interface 110 may receive the request REQ from the host 20, receive the data DIO read from the memory device 200 through the memory interface 140, and transfer the received data DIO to the host 20.

The control module 120 may receive the request REQ from the host 20 through the host interface 110. The control module 120 may control each component of the memory controller 100 according to the request REQ. The control module 120 may generate various commands (e.g., an active command, a precharge command, a read command, a write command, etc.) and address, according to the request REQ. For example, the control module 120 may generate an address to be activated together with an active command, and generate an address to be read or written together with a read command or a write command. Hereinafter, a command and address generated in response to the request REQ from the host 20 is referred to as a host-requested command and address.

The control module 120 may set the order of requests to be instructed to the memory device 200 among the requests REQs from the host 20 and generate a command to be applied to the memory device 200 according to the order of the predetermined operations. To improve the performance of the memory device 200, the control module 120 may change the order in which the requests REQs are received from the host 20 and the order of the operations to be instructed to the memory device 200. For example, the control module 120 may adjust the order so that a write operation is performed before a read operation, even if the host 20 requests the read operation of the memory device 200 first and the write operation later.

The ECC engine 130 may check and correct an error in the data DIO read from the memory device 200, and generate error information and error-corrected data. When the number of error bits of the data DIO is out of the error correction capability of the ECC engine 130, the control module 120 may notify the host 20 that an uncorrectable error UE has occurred.

The memory interface 140 may be configured to communicate with the memory device 200. The memory interface 140 may transmit the command/address signal C/A and the data DIO to the memory device 200, and receive the data DIO read from the memory device 200. For example, the memory interface 140 may provide the command/address signal C/A corresponding to a command and address generated by the control module 120 to the memory device 200. In addition, the memory interface 140 may provide the data DIO corresponding to the request REQ provided from the host interface 110 to the memory device 200.

The fault analysis module 150 may generate error logging information (e.g., an error log) based on the error information generated by the ECC engine 130, and generate a faulty address by analyzing the error log.

The scrub management module 160 may control the memory device 200 to perform an adaptive scrub operation including a first scrub operation and a second scrub operation. In an embodiment of the present disclosure, the scrub management module 160 may control the memory device 200 to perform the second scrub operation on adjacent addresses specified within a fault boundary, based on a faulty address detected through the first scrub operation. It is noted that the adjacent addresses may correspond to addresses for specifying one or more rows (hereinafter referred to as “adjacent rows”) adjacent to a faulty row (or a faulty row) designated by the faulty address. Details of the adaptive scrub operation according to an embodiment of the present disclosure will be described later.

Meanwhile, the memory controller 100 may transmit data between the host interface 110, the control module 120, the ECC engine 130, the memory interface 140, the fault analysis module 150, and the scrub management module 160 through the bus 170. According to an embodiment, the host interface 110, the control module 120, the ECC engine 130, the memory interface 140, the fault analysis module 150, and the scrub management module 160 may communicate with each other independently without passing through the bus 170. For example, the fault analysis module 150 and the host interface 110 may communicate directly with each other without passing through the bus 170, and the host interface 110 and the memory interface 140 may also communicate directly with each other without passing through the bus 170.

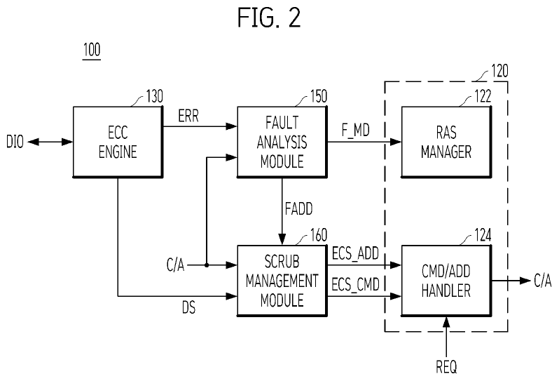

FIG. 2 is a detailed block diagram illustrating a portion of a memory controller shown in FIG. 1.

Referring to FIG. 2, a control module 120, an ECC engine 130, a fault analysis module 150, and a scrub management module 160 of a memory controller 100 are shown.

The ECC engine 130 may generate an error signal ERR by checking an error of the data DIO read from a memory device 200 of FIG. 1, and may generate error-corrected data by correcting the error of the data DIO. In addition, the ECC engine 130 may generate a decoding status signal DS according to an error correction result. The error signal ERR is a signal that includes information on whether an error has occurred in the read data DIO and the number of error bits, and the decoding status signal DS is a signal that includes information on whether the error is a correctable error (CE), an uncorrectable error (UE), or a no-error (NE). The error signal ERR and the decoding status signal DS may be collectively referred to as the “error information.” During a read operation, the error-corrected data may be provided to a host 20 through a host interface 110 of FIG. 1. During an adaptive scrub operation, the error-corrected data may be provided to the memory device 200 through a memory interface 140.

During a write operation, the ECC engine 130 may generate parity bits using data provided from the host 20 and may provide data DIO including both the data and the parity bits to the memory device 200 through the memory interface 140.

The fault analysis module 150 may generate an error log by accumulating the error signals ERR generated during the error check operations, and may detect a faulty address FADD by analyzing the error log. The fault analysis module 150 may generate the error log by accumulating the error signals ERR for a single row based on the command/address signal C/A, and may analyze the error log to determine whether the corresponding row is a faulty row, thereby detecting the faulty address FADD. For example, when an accumulated error count occurring in a row exceeds a threshold value, the fault analysis module 150 may determine that the row is a faulty row and may generate a faulty address FADD corresponding to the row. In an embodiment of the present disclosure, the faulty address FADD may include a row address that designates a faulty row. In the following description, the faulty address FADD will be described as a faulty row address. However, the present disclosure is not limited thereto, and for example the faulty address FADD may include both a row address that designates a faulty row and a column address that designates a faulty column.

The fault analysis module 150 may collect faulty row addresses FADD during the adaptive scrub operation and may analyze a failure of the memory device 200 based on the collected faulty row addresses FADD to generate fault mode information F_MD. The fault analysis module 150 may include a plurality of address registers and may sequentially store the faulty row addresses FADD in the address registers each time they are detected. The fault analysis module 150 may analyze a relationship between the stored faulty row addresses FADD to generate the fault mode information F_MD. The fault analysis module 150 may provide the faulty row address FADD to the scrub management module 160 and the fault mode information F_MD to the control module 120. The fault analysis module 150 may also be referred to as a fault analysis device and may be disposed outside the memory controller 100 to provide the faulty row address FADD and the fault mode information F_MD to the memory controller 100.

The scrub management module 160 may generate a scrub command ECS_CMD instructing a first scrub operation and a scrub address ECS_ADD designating memory cells to be scrubbed. The scrub address ECS_ADD may include both row and column addresses. When the faulty row address FADD is detected from the fault analysis module 150 by the first scrub operation, the scrub management module 160 may generate a scrub command ECS_CMD and a scrub address ECS_ADD to perform a second scrub operation on adjacent row addresses specified within a fault boundary based on the faulty row address FADD. Here, the adjacent row addresses may be addresses for designating one or more adjacent rows adjacent to the faulty row corresponding to the faulty row address FADD. The scrub command ECS_CMD and the scrub address ECS_ADD generated by the scrub management module 160 may be provided to the control module 120.

Meanwhile, the scrub management module 160 may include a non-volatile memory for maintaining the faulty row address FADD even after power-down or power-off. The non-volatile memory may be configured as one of non-volatile memories such as an array e-fuse (ARE) circuit, a laser fuse circuit, a NAND flash memory, a NOR flash memory, a magnetic random access memory (MRAM), a spin transfer magnetic random access memory (STT-MRAM), a resistive random access memory (ReRAM), and a phase change random access memory (PC RAM).

In an embodiment of the present disclosure, the first scrub operation may include at least one of a patrol scrub operation and a demand scrub operation, and the second scrub operation may include a designated scrub operation.

The patrol scrub operation is performed to detect and correct errors in advance by patrolling memory cells that are not accessed by the host 20. The patrol scrub operation may be performed as a background operation. During the patrol scrub operation, scrub operations may be performed on all memory cells of the memory device 200 over a predetermined period (for example, 24 hours). Each scrub operation may include a read operation for reading data from the memory device 200, an error check operation for checking and correcting an error in the read data, and a write operation (hereinafter referred to as a “write-back operation”) for writing error-corrected data back to the memory device 200. The scrub management module 160 may perform the patrol scrub operation by generating the scrub command ECS_CMD and the scrub address ECS_ADD as many times as needed to check errors of all memory cells of the memory device 200 within a predetermined period. During each scrub operation, the scrub management module 160 may generate the scrub command ECS_CMD instructing the read and write-back operations together with the scrub address ECS_ADD designating memory cells to be scrubbed, and the ECC engine 130 may perform the error check and correction operation on the data DIO read from the memory device 200 according to the scrub command ECS_CMD and the scrub address ECS_ADD.

The demand scrub operation is performed to correct an error in memory cells (hereinafter, referred to as “target memory cells”) accessed according to the request REQ from the host 20. During the demand scrub operation, scrub operations may be performed on the target memory cells. For example, during a read operation on the target memory cells according to the request REQ from the host 20, the demand scrub operation may be performed by writing back data DIO error-corrected by the ECC engine 130 to the target memory cells. The scrub management module 160 may perform the demand scrub operation by generating the scrub command ECS_CMD instructing the writing of the error-corrected data DIO to the target memory cells together with the scrub address ECS_ADD designating the target memory cells. It is noted that, to perform the demand scrub operation, the scrub management module 160 may receive the command/address signal C/A.

The designated scrub operation is performed to check errors of memory cells connected to one or more adjacent rows specified within a fault boundary based on a faulty row detected as a result of the patrol scrub or demand scrub operation. During the designated scrub operation, scrub operations may be performed on memory cells connected to the adjacent rows. Each scrub operation may include a read operation for reading data from the memory device 200, an error check operation for checking and correcting an error in the read data, and a write-back operation for writing error-corrected data back to the memory device 200. The scrub management module 160 may perform the designated scrub operation by setting a fault boundary based on criteria described later, and generating the scrub command ECS_CMD and the scrub address ECS_ADD as many times as needed to check errors of memory cells connected to the adjacent rows specified within the fault boundary.

The scrub management module 160 may receive, in addition to the faulty row address FADD, the command/address signal C/A and the decoding status signal DS to control the read operation, the error check operation, and the write-back operation of the first and second scrub operations.

The control module 120 may include a reliability, availability, and serviceability (RAS) manager 122 and a command/address handler 124.

The RAS manager 122 may perform a RAS operation to improve the reliability of the memory device 200 based on the fault mode information F_MD. In an embodiment, when the fault mode information F_MD is output from the fault analysis module 150, the control module 120 may store the fault mode information F_MD as repair information. For example, the control module 120 may store the repair information in a non-volatile memory such as an E-fuse array so that the stored repair information is maintained even when the memory system 10 is powered off. The RAS manager 122 may perform the RAS operation according to the stored repair information on power-up.

For example, the RAS manager 122 may generate a command and address for instructing the memory device 200 to perform the RAS operation, or may request the host 20 to perform the RAS operation. The RAS manager 122 may request the memory device 200 to perform a post-package repair operation or an error correction operation according to the fault mode information F_MD related to a particular row. The RAS manager 122 may request the host 20 to perform a page offlining operation or a row remapping operation to exclude the use of two or more rows according to the fault mode information F_MD related to the two or more rows. The RAS manager 122 may also request the host 20 to perform a bank spare/migration operation to replace a bank, or to determine that the corresponding memory device 200 is no longer usable, according to the fault mode information F_MD indicating that multiple defects with unclear causes have occurred in a particular bank among a plurality of banks.

The command/address handler 124 may generate the host-requested command and address according to the request REQ from the host 20. The command/address handler 124 may receive the scrub command ECS_CMD and the scrub address ECS_ADD from the scrub management module 160. Although not shown, the command/address handler 124 may also generate a refresh command for a refresh operation, in addition to the scrub command ECS_CMD and the scrub address ECS_ADD. The command and address generated internally for an internal operation such as the scrub operation or the refresh operation, regardless of the request REQ from the host 20, may be defined as an internal-requested command and address. The command/address handler 124 may generate the command/address signal C/A by scheduling the generation of the host-requested command and address and the internal-requested command and address. The command/address signal C/A may be provided to the memory device 200 through the memory interface 140.

FIG. 2 illustrates an example in which the RAS manager 122 is included in the control module 120; however, the proposed disclosure is not limited thereto, and the RAS manager 122 may be configured separately from the control module 120. Furthermore, although the components of the control module 120 required in an embodiment of the present disclosure are illustrated in FIG. 2, the control module 120 may include additional components as needed in other embodiments.

Hereinafter, with reference to the drawings, a structure of a memory cell array 210 of FIG. 1 and a fault boundary according to an embodiment of the present disclosure will be described.

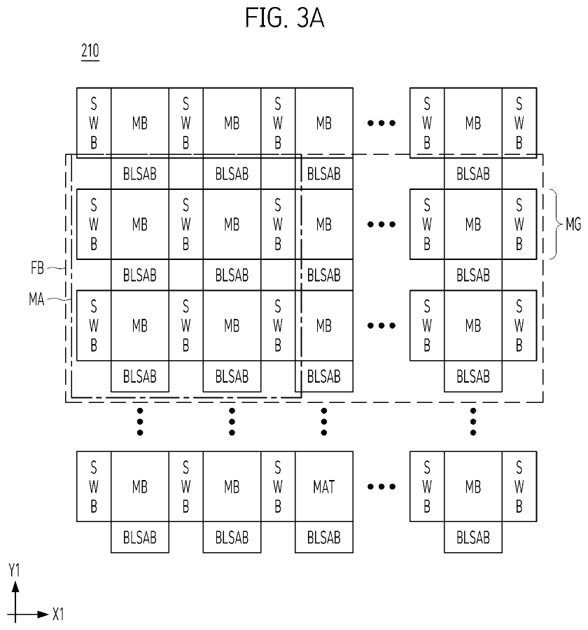

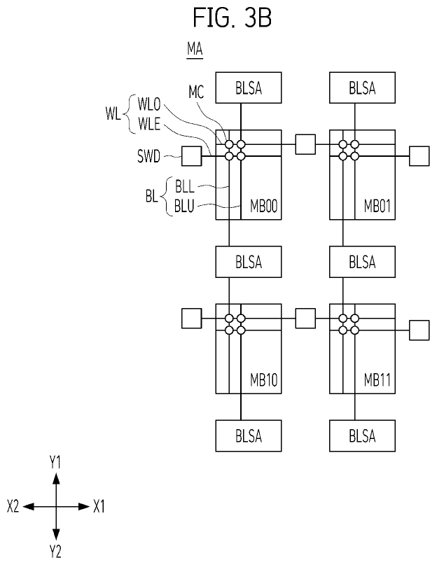

FIGS. 3A and 3B are diagrams for describing a memory cell array of FIG. 1.

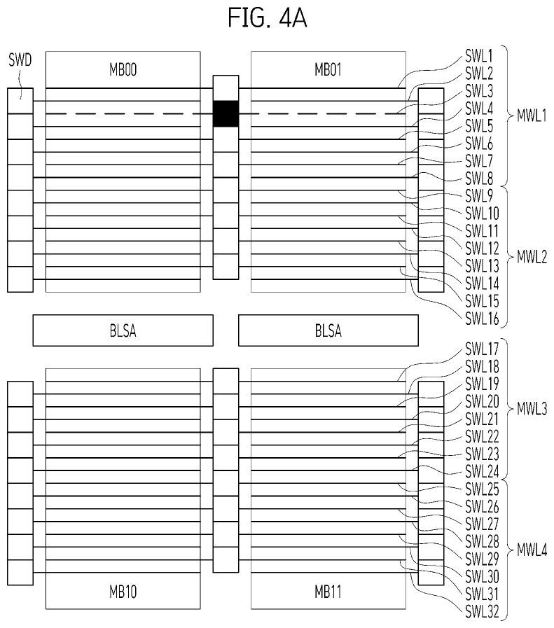

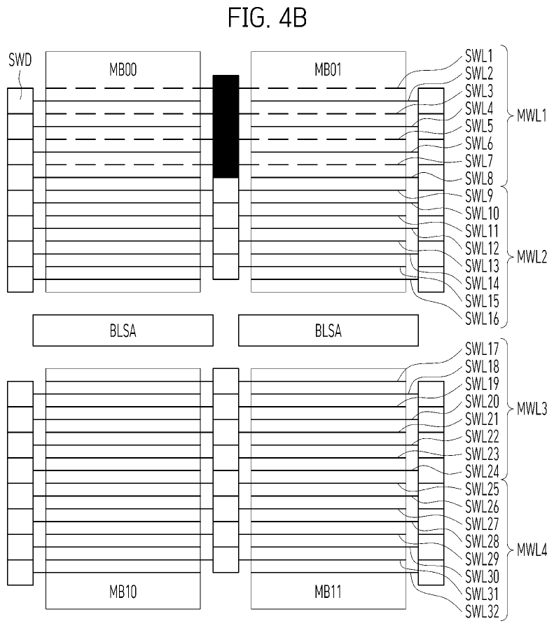

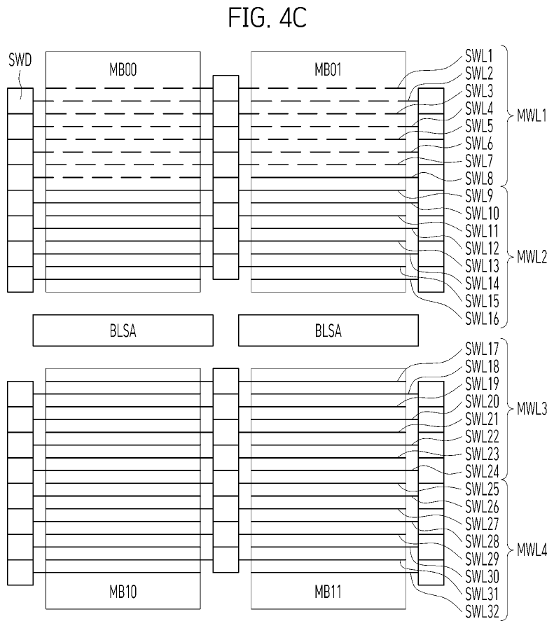

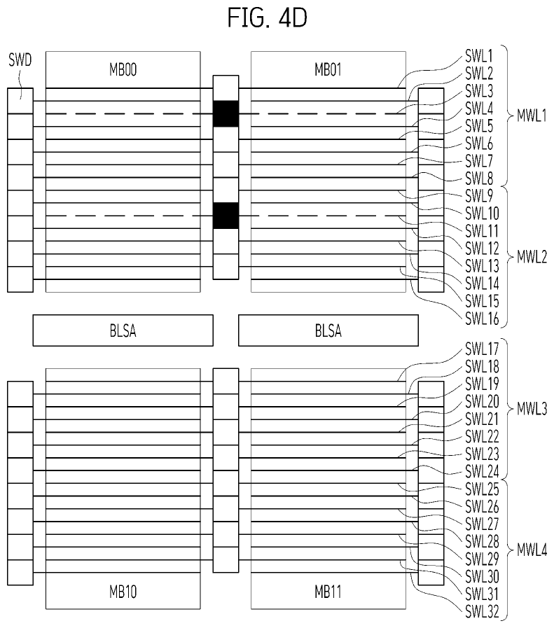

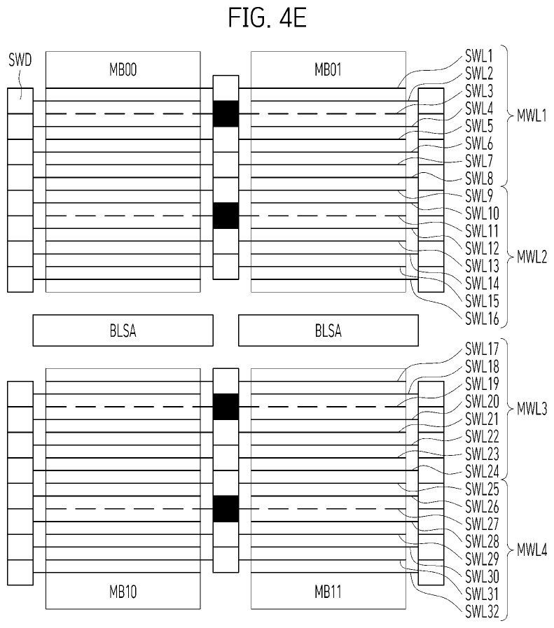

Referring to FIG. 3A, a memory cell array 210 may include a plurality of cell blocks MB arranged in an array form in a first direction X1 (hereinafter, referred to as a “row direction X1”) and a second direction Y1 (hereinafter, referred to as a “column direction Y1”), which intersects the row direction X1. Each cell block MB may include a plurality of memory cells (MC of FIG. 3B) connected between a plurality of word lines (WL of FIG. 3B) and a plurality of bit lines (BL of FIG. 3B). The cell blocks MB arranged in the row direction X1 may be divided into the bit lines BL, and the cell blocks MB arranged in the column direction Y1 may be divided into the word lines WL. Sub-word line driver regions SWB may be arranged between the cell blocks MB in the row direction X1. A plurality of sub-word line drivers (SWD of FIG. 4B) may be disposed in the sub-word line driver region SWB. Bit line sense amplifier regions BLSAB may be arranged between the cell blocks MB in the column direction Y1. A plurality of bit line sense amplifiers (BLSA of FIG. 4B) may be disposed in the bit line sense amplifier region BLSAB. In an embodiment of the present disclosure, the “cell block” may be defined as a set of memory cells that share word lines WL and bit lines BL and that are arranged in the same manner.

For reference, in order to reduce propagation delay of a word line voltage, which occurs as the number of memory cells connected to the word lines increases and a distance between the word lines decreases, one main word line may be divided into a plurality of (e.g., eight) sub-word lines, which are driven by the sub-word line drivers. Hereinafter, the word lines WL mentioned in the present disclosure may correspond to known sub-word lines, and the sub-word line drivers may be referred to as word line drivers.

In an embodiment, when a group of cell blocks arranged in the row direction X1 among the plurality of cell blocks MB is defined as a cell group MG, n (where n is an integer equal to or greater than 2) or more cell groups that are adjacent in the column direction Y1 may be set as a fault boundary. For example, when n is set to 2, the scrub management module 160 may set, as one fault boundary, a cell group in which the faulty row corresponding to the faulty row address is located, and a cell group adjacent thereto in the column direction Y1 (or a direction opposite to the column direction Y1). In the following embodiment, a case in which two cell groups adjacent in the column direction Y1 are set as a fault boundary FB will be described as an example.

Referring to FIG. 3B, a partial area MA for adjacent 2×2 cell blocks MB00 to MB11 included in a fault boundary FB of FIG. 3A is illustrated.

The squares between the cell blocks MB00 and MB01 or MB10 and MB11 that are adjacent in the row direction X1 represent sub-word line drivers SWD, and the lines extending to the left and right of the sub-word line drivers SWD may represent word lines WL. In reality, a much larger number of sub-word line drivers SWD and word lines exist, but only a part of the lines are shown to simplify the illustration in FIG. 3B.

Each of the cell blocks MB00 to MB11 may include odd-numbered word lines (hereinafter, referred to as “first word lines WLO”) and even-numbered word lines (hereinafter, referred to as “second word lines WLE”) extending in the row direction X1 and alternating with each other in the column direction Y1. In odd-numbered cell blocks MB00 and MB10, the first word lines WLO may share sub-word line drivers SWD with an adjacent cell block in the row direction X1, and the second word lines WLE may share sub-word line drivers SWD with an adjacent cell block in a direction X2 opposite to the row direction X1. Conversely, in even-numbered cell blocks MB01 and MB11, the second word lines WLE may share sub-word line drivers SWD with an adjacent cell block in the row direction X1, and the first word lines WLO may share sub-word line drivers SWD with an adjacent cell block in the direction X2. That is, since two adjacent cell blocks in the row direction X1 share sub-word line drivers SWD, one sub-word line driver SWD may be allocated to two adjacent cell blocks in the row direction X1 or X2.

Each of the cell blocks MB00 to MB11 may include first bit lines BLU and second bit lines BLL extending in the column direction Y1 and alternately disposed in the row direction X1. The first bit lines BLU may share bit line sense amplifiers BLSA with an adjacent cell block (not illustrated) in the column direction Y1, and the second bit lines BLL may share bit line sense amplifiers BLSA with an adjacent cell block (not illustrated) in a direction Y2 opposite to the column direction Y1. That is, since two adjacent cell blocks in the column direction Y1 share bit line sense amplifiers BLSA, one bit line sense amplifier BLSA may be allocated to two adjacent cell blocks in the column direction Y1 or Y2.

Various analyses have shown that most failures in current DRAM devices exhibit a tendency of bounded faults occurring in adjacent cell blocks, which is considered to be associated with defect patterns resulting from the hierarchical architecture of DRAM devices.

FIGS. 4A to 4E are diagrams illustrating fault types that may occur within a fault boundary according to an embodiment of the present disclosure.

FIGS. 4A to 4E illustrate two main word lines arranged per one cell block and eight sub-word lines assigned to each main word line. For example, in upper cell blocks MB00 and MB01, sixteen sub-word lines (i.e., rows SWL1 to SWL16) extend in a row direction and are alternately arranged in a column direction, with eight sub-word lines assigned to each of the two main word lines MWL1 and MWL2. In lower cell blocks MB10 and MB11, sixteen sub-word lines (i.e., rows SWL17 to SWL32) extend in the row direction and are alternately arranged in the column direction, with eight sub-word lines assigned to each of the two main word lines MWL3 and MWL4. In the row direction on both sides of each cell block MB00 to MB11, sixteen sub-word line drivers SWD for driving the respective sub-word lines may be alternately arranged in the column direction. For example, eight sub-word line drivers disposed on one side of each cell block drive the odd-numbered sub-word lines, while eight sub-word line drivers disposed on the opposite side drive the even-numbered sub-word lines. Among the sixteen sub-word line drivers SWD disposed on both sides of each cell block, the upper eight sub-word line drivers are connected to the upper main word line (for example, MWL1 or MWL3), and the lower eight sub-word line drivers are connected to the lower main word line (for example, MWL2 or MWL4).

FIG. 4A illustrates one (indicated by a black box) of the eight sub-word line drivers between the cell blocks MB00 and MB01, which are adjacent in the row direction, is defective. In this case, an accumulated error count generated from the data output through the sub-word line SWL3 (indicated by a dotted line) connected to both arms of the defective sub-word line driver may exceed a threshold value, causing the sub-word line SWL3 to be detected as a faulty row.

FIG. 4B illustrates all the sub-word line drivers (indicated by black boxes) connected to the upper main word line MWL1, from among the plurality of sub-word line drivers between the cell blocks MB00 and MB01 which are adjacent in the row direction, are defective. In this case, an accumulated error count generated from the data output through the sub-word lines connected to both arms of the defective sub-word line drivers—that is, the odd-numbered sub-word lines SWL1, SWL3, SWL5, and SWL7 (indicated by dotted lines) connected to the upper main word line MWL1 of the cell blocks MB00 and MB01—may exceed a threshold value, causing the sub-word lines SWL1, SWL3, SWL5, and SWL7 to be detected as faulty rows.

FIG. 4C illustrates a defective upper main word line MWL1 between the cell blocks MB00 and MB01, which are adjacent in the row direction. In this case, an accumulated error count generated from the data output through all the sub-word lines SWL1 to SWL8 (indicated by dotted lines) connected to the upper main word line MWL1 of the cell blocks MB00 and MB01 may exceed a threshold value, causing the sub-word lines SWL1 to SWL8 to be detected as faulty rows.

FIG. 4D illustrates defective sub-word line drivers having the same sequence number (for example, the third in sequence of the sub-word lines of the upper main word line MLW1 and the third in sequence of the sub-word lines of the upper main word line MLW2), among the eight sub-word line drivers respectively connected to the upper main word line MWL1 and the lower main word line MWL2 between the cell blocks MB00 and MB01, which are adjacent in the row direction. In this case, an accumulated error count generated from the data output through the sub-word lines SWL3 and SWL11 (indicated by dotted lines) having the same sequence number as the defective sub-word line drivers connected to both arms of the defective sub-word line drivers of the cell blocks MB00 and MB01 may exceed a threshold value, causing the sub-word lines SWL3 and SWL11 to be detected as faulty rows.

FIG. 4E illustrates sub-word line drivers having the same sequence number (for example, the third sequence number) respectively connected to the upper main word lines MWL1 and MWL3 and the lower main word lines MWL2 and MWL4, from among the plurality of sub-word line drivers between the cell blocks MB00 and MB01 and between the cell blocks MB10 and MB11, are defective. In this case, an accumulated error count generated from the data output through the sub-word lines SWL3, SWL11, SWL19, and SWL27 (indicated by dotted lines) having the same sequence number as the defective sub-word line drivers connected to both arms of the defective sub-word line drivers of all the adjacent cell blocks MB00 to MB11 may exceed a threshold value, causing the sub-word lines SWL3, SWL11, SWL19, and SWL27 to be detected as faulty rows.

In an embodiment, the scrub management module 160 may set two cell groups adjacent in the column direction as the fault boundary FB, and perform an adaptive scrub operation on a faulty row and adjacent rows within the set fault boundary FB. For example, as shown in FIG. 4A, when a sub-word line SWL3 connected to both arms of a defective sub-word line driver is detected as a faulty row according to the result of the first scrub operation, the scrub management module 160 may perform a designated scrub operation on all or some of the adjacent rows, e.g., SWL1 to SWL8, SWL11, SWL19, and SWL27 arranged in the two cell groups adjacent in the column direction, as illustrated in FIGS. 4B to 4E.

However, the present disclosure is not limited thereto, and the adjacent rows may be specified according to the fault types that may occur within the fault boundary FB. For example, when a sub-word line SWL3 connected to both arms of a defective sub-word line driver is detected as a faulty row according to the result of the first scrub operation, the scrub management module 160 may perform a designated scrub operation on all adjacent rows SWL1 to SWL16 arranged in the cell blocks MB00 and MB01 in the same row direction.

The fault analysis module 150 may generate the fault mode information F_MD by analyzing the fault types among the faulty rows within the set fault boundary FB based on the result of the adaptive scrub operation. For example, the fault analysis module 150 may determine that one sub-word line driver driving a single sub-word line is defective when errors occur only in the data output from the single sub-word line (see FIG. 4A). The fault analysis module 150 may determine that that odd-numbered (or even-numbered) sub-word line drivers connected to a main word line are defective when errors occur in the data output from the odd-numbered (or the even-numbered) sub-word lines connected to the main word line (see FIG. 4B). In this case, the fault may be caused by a failure occurring in a contact or a common signal line shared by the odd-numbered (or even-numbered) sub-word line drivers. The fault analysis module 150 may determine that a main word line itself is defective when errors occur in the data output from almost all sub-word lines connected to one main word line (see FIG. 4C).

Further, when errors occur in the data output from sub-word lines having the same sequence number among the sub-word lines respectively connected to two adjacent main word lines (see FIG. 4D), the fault analysis module 150 may determine that sub-word line drivers driving the corresponding sub-word lines are defective. In this case, the fault may be caused by a failure occurring in a contact shared by the sub-word line drivers. When errors occur in the data output from sub-word lines having the same sequence number among the sub-word lines connected to each of all the main word lines (see FIG. 4E), the fault analysis module 150 may determine that sub-word line drivers driving the corresponding sub-word lines are defective. In this case, the fault may be caused by a failure occurring in a signal path commonly provided to the sub-word line drivers.

Meanwhile, the present disclosure is not limited thereto, and the fault analysis module 150 may analyze various fault types and generate the fault mode information F_MD based on the result of the adaptive scrub operation performed on the faulty row and the adjacent rows within the set fault boundary FB.

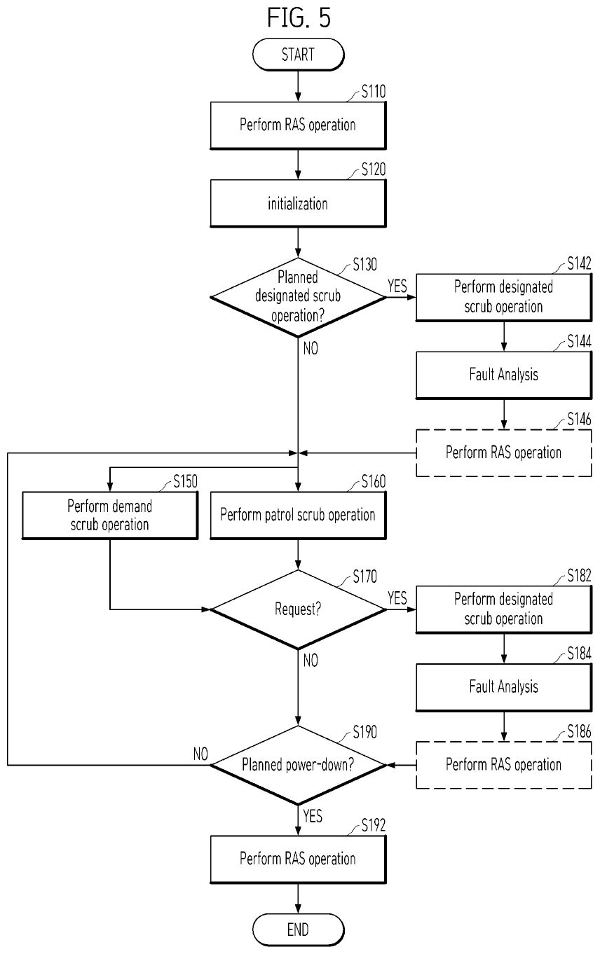

Hereinafter, referring to FIG. 5, an adaptive scrub operation according to an embodiment of the present disclosure will be described in detail.

FIG. 5 is a flowchart for describing an adaptive scrub operation according to an embodiment of the present disclosure.

Referring to FIG. 5, first, upon power-up, the memory system 10 may perform a reliability, availability, and serviceability (RAS) operation to enhance the reliability of the memory device 200 (at S110). For example, the memory system 10 may perform a post-package repair operation, a page offlining operation, a row remapping operation, or a bank spare/migration operation.

The memory system 10 may perform an initialization operation (at S120). During the initialization operation, the memory system 10 may execute an initialization sequence defined in the JEDEC standard. For example, the memory system 10 may perform an internal circuit initialization operation such as voltage level stabilization and clock stabilization between the memory controller 100 and the memory device 200. In addition, the memory system 10 may perform an initialization operation such as mode register set (MRS) configuration, ZQ calibration, and impedance matching of the memory device 200. Although the RAS operation (at S110) and the initialization operation (at S120) are described separately in FIG. 5, the RAS operation (at S110) may be performed during the initialization operation (at S120) depending on an embodiment.

Thereafter, the scrub management module 160 of the memory controller 100 may determine whether a planned (or scheduled) designated scrub operation exists (at S130). If a faulty row address FADD detected during a previous operation has not yet been scrubbed before power-down, the planned designated scrub operation may be performed on the faulty row address FADD. However, the present disclosure is not limited thereto, and the planned designated scrub operation may also be performed according to stored repair information after initialization.

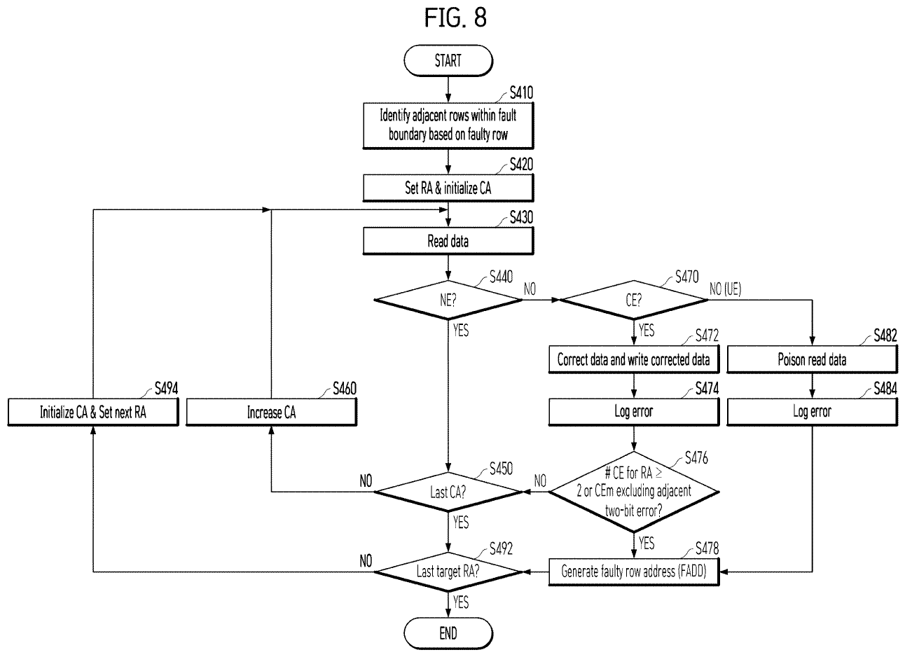

When the planned designated scrub operation exists (“YES” in S130), the scrub management module 160 may perform the designated scrub operation on the faulty row address FADD detected during the previous operation (at S142). The scrub management module 160 may set a fault boundary FB and generate a scrub command ECS_CMD and a scrub address ECS_ADD for a number of times corresponding to error checks on memory cells connected to the adjacent rows specified within the fault boundary FB based on the faulty row. For example, as shown in FIG. 4A, when the faulty row address FADD corresponding to the sub-word line SWL3 is stored, the scrub management module 160 may generate a scrub command ECS_CMD and a scrub address ECS_ADD to perform a designated scrub operation on adjacent rows SWL1 to SWL8, SWL11, SWL19, and SWL27 arranged in two cell groups adjacent in the column direction, as shown in FIGS. 4B-4E. Meanwhile, the designated scrub operation performed during initialization corresponds to a first type of the designated scrub operation, the detailed process of which will be described with reference to FIG. 8.

The fault analysis module 150 may generate fault mode information F_MD by analyzing the fault types for the faulty rows detected as a result of the designated scrub operation (at S144).

After the planned designated scrub operation (at S142) and the fault analysis (at S144) are completed, the RAS manager 122 may selectively perform a RAS operation to improve the reliability of the memory device 200 based on the fault mode information F_MD (at S146). For example, the RAS manager 122 may control the memory system to perform a post-package repair operation, a page offlining operation, a row remapping operation, or a bank spare/migration operation. The RAS operation (at S146) may be performed during runtime depending on product specifications, or it may be omitted if runtime execution is impractical. In FIG. 5, the RAS operation (at S146) is shown in dashed lines to indicate that it is optional.

Thereafter, the memory system 10 may perform a normal operation such as a read operation or a write operation in response to a request REQ from the host 20.

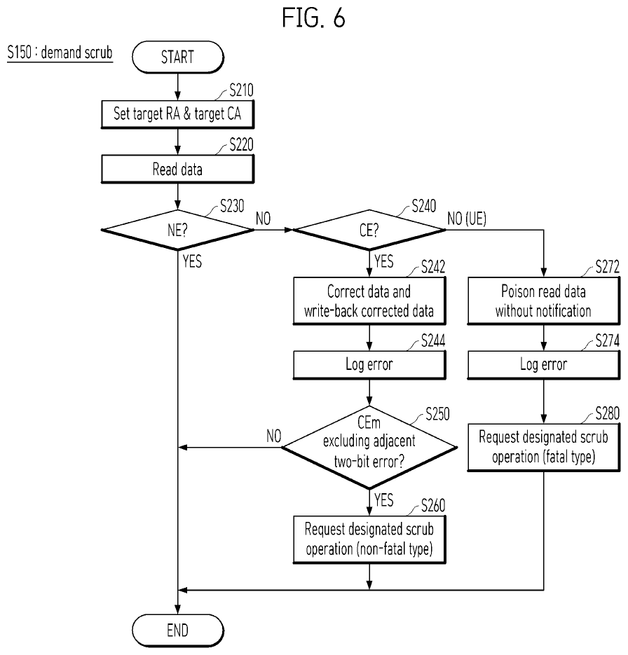

The scrub management module 160 may perform a demand scrub operation on data DIO read from target memory cells of the memory device 200 during a read operation (at S150). The ECC engine 130 may check for an error in the data DIO read from the target memory cells, generate an error signal ERR, and correct the error to produce error-corrected data. The error-corrected data may then be provided to the host 20 through the host interface 110. At this time, the scrub management module 160 may perform the demand scrub operation by writing back the error-corrected data to the target memory cells. The detailed process of the demand scrub operation will be described with reference to FIG. 6. The fault analysis module 150 may generate a faulty row address FADD for the target memory cells according to the error signal ERR generated during the error check operation on the data DIO.

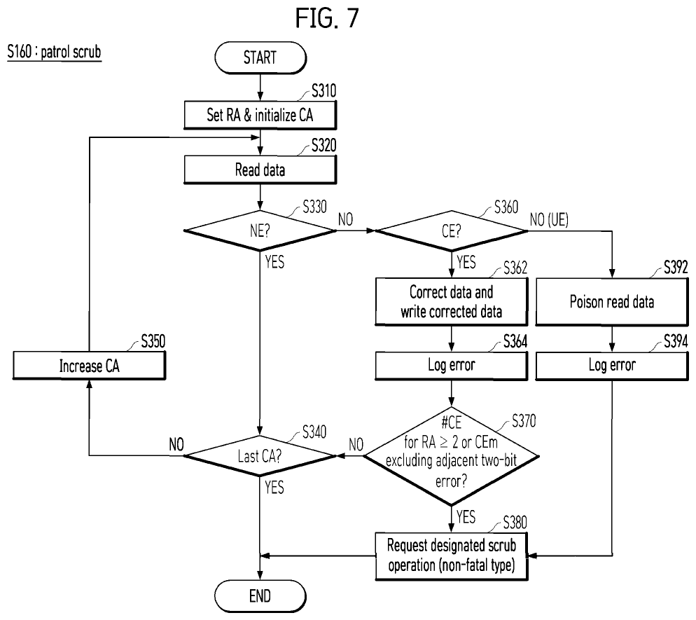

The scrub management module 160 may perform a patrol scrub operation for all memory cells of the memory device 200 at predetermined intervals (e.g., every 24 hours) (at S160). The scrub management module 160 may perform a scrub operation including a read operation for reading data from memory cells, an error check operation and correction operation for the read data, and a write-back operation for writing the corrected data back into the memory device 200 on a per-row basis. The detailed process of the patrol scrub operation performed for each row will be described with reference to FIG. 7. The fault analysis module 150 may generate a faulty row address FADD corresponding to a row according to the error signal ERR generated during the patrol scrub operation.

When a designated scrub operation is requested because a faulty row address FADD is detected as a result of a demand scrub or patrol scrub operation (“YES” in S170), the scrub management module 160 may perform the designated scrub operation for the detected faulty row address FADD (at S182), and the fault analysis module 150 may analyze the fault types among the faulty rows based on the results of the designated scrub operation to generate fault mode information F_MD (at S184). Thereafter, the RAS manager 122 may selectively perform a RAS operation to improve the reliability of the memory device 200 based on the fault mode information F_MD (at S186). For example, the RAS manager 122 may control the memory system to perform a post-package repair operation, a page offlining operation, a row remapping operation, or a bank spare/migration operation. The RAS operation (at S186) may be performed during runtime depending on product specifications, or it may be omitted if runtime execution is impractical. In FIG. 5, the RAS operation (at S186) is also shown in dashed lines to indicate that it is optional.

Until a planned power-down (“NO” in S190) occurs, the above operations (S150 to S186) may be repeatedly performed. That is, when a designated scrub operation is requested (“YES” in S170) since a faulty row address FADD is detected as a result of a demand scrub operation (at S150) or a patrol scrub operation (at S160), the designated scrub operation may be performed on the detected faulty row address FADD (at S182), and a corresponding RAS operation may be selectively executed (at S186).

When the planned power-down occurs (“YES” in S190), the RAS manager 122 may perform a RAS operation based on the fault mode information F_MD (at S192). Accordingly, the operation of the memory system 10 may be completed.

Depending on product specifications, only one of the demand scrub operation and the patrol scrub operation may be performed, rather than both. For example, in a product configured to perform only the demand scrub operation, when a faulty row is detected as a result of the demand scrub operation, an additional designated scrub operation may be performed on adjacent rows specified within the fault boundary based on the detected faulty row. Alternatively, in a product configured to perform only the patrol scrub operation, when a faulty row is detected as a result of the patrol scrub operation, an additional designated scrub operation may be performed on adjacent rows specified within the fault boundary based on the detected faulty row.

As described above, in embodiments of the present disclosure, when the faulty row is detected as a result of the demand scrub operation or the patrol scrub operation, the designated scrub operation may be performed on the adjacent rows specified within the fault boundary based on the detected faulty row. Accordingly, it is possible to accurately determine the fault types, and to identify errors that have a potential to develop into uncorrectable errors (UEs) according to the fault types, thereby enabling the optimized RAS operation.

FIG. 6 is a flowchart for describing a demand scrub operation according to an embodiment of the present disclosure.

Referring to FIG. 6, a demand scrub operation (at S150 in FIG. 5) performed during a read operation is illustrated.

During a read operation, a command/address handler 124 may set a row address and a column address to designate target memory cells to be read according to a request REQ from a host 20 (at S210). Hereinafter, the row address and column address for designating target memory cells are referred to as a target row address RA and a target column address CA, respectively. The memory device 200 may read data DIO from the target memory cells corresponding to the target row address RA and the target column address CA (at S220).

If the read data DIO has no error (NE) (“YES” in S230), the read data DIO is provided to the host 20, and the process may be finished.

If a correctable error (CE) is detected in the read data DIO (“NO” in S230 & “YES” in S240), an ECC engine 130 may correct an error in the read data DIO. The scrub management module 160 generates a scrub command ECS_CMD and a scrub address ECS_ADD instructing a write-back operation, and accordingly, the error-corrected data may be written back to the target memory cells (at S242). The fault analysis module 150 may log the error based on an error signal ERR provided from the ECC engine 130 (at S244).

Generally, the ECC engine 130 of the memory controller 100 may correct a multi-bit error or a symbol-level error. When an adjacent two-bit error occurs in a single row, they can be handled similarly to a single-bit error. However, when a correctable multi-bit error (CEm), except for the adjacent two-bit error, occurs in a row, the row may be considered a potential faulty row. In an embodiment, when the correctable error (CE) is a single-bit error or an adjacent two-bit error (“NO” in S250), the process may be finished. On the other hand, when the correctable error (CE) is a multi-bit error (CEm) except for the adjacent two-bit error (“YES” in S250), the fault analysis module 150 may generate a faulty row address FADD corresponding to the target row address RA and request the scrub control module 160 to perform a first type (or a non-fatal type) of a designated scrub operation for the faulty row address FADD (at S260). The demand scrub process may then be finished.

If an uncorrectable error (UE) is detected in the read data DIO (“NO (UE)” in S240), the ECC engine 130 may poison the read data DIO (at S272). In this case, the ECC engine 130 may provide a specific pattern indicating that the read data DIO is corrupted to the host 20 instead of the read data DIO, thereby performing data poisoning. Generally, during the demand scrub operation, notifying the host 20 that the data is poisoned may improve reliability. However, in an embodiment, the notification operation may be omitted during the demand scrub operation (at S272) and may be performed during a second type (or a fatal type) of a designated scrub operation described later.

The fault analysis module 150 may log the error according to an error signal ERR provided from the ECC engine 130 (at S274). The fault analysis module 150 may generate a faulty row address FADD corresponding to the target row address RA and request the scrub control module 160 to perform the second type of the designated scrub operation for the faulty row address FADD (at S280). The demand scrub process may then be ended. During the second type of the designated scrub operation described below, a notification that the data is poisoned may be performed.

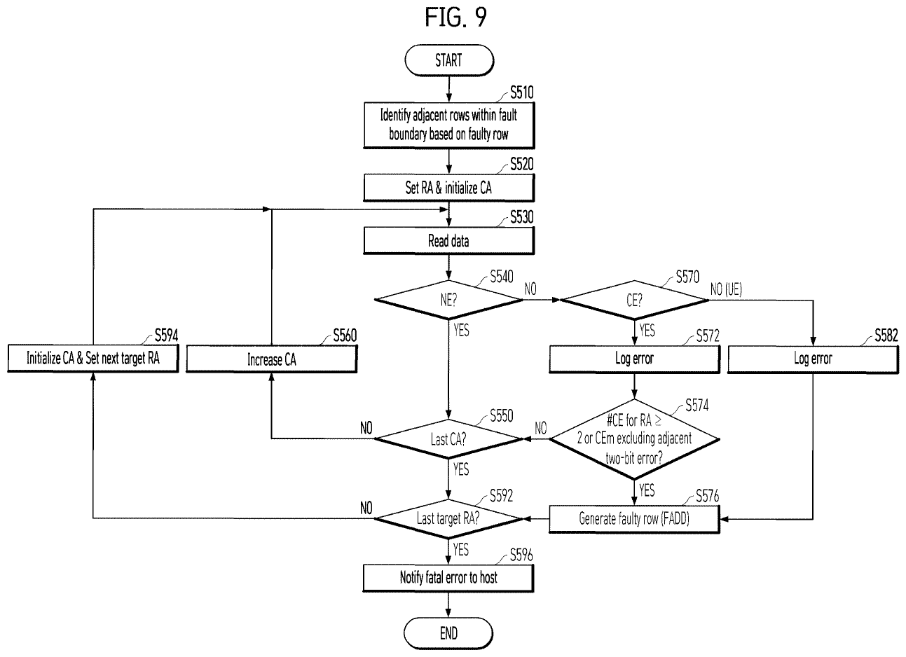

The first type of the designated scrub operation is defined as a non-fatal type, and the second type of the designated scrub operation is defined as a fatal type. The second type of the designated scrub operation is performed in more severe situations compared to the first type, and may omit a write-back operation in CE situations or poisoning in UE situations, while performing a notification operation of an occurrence of a poison error to the host 20. The first type of designated scrub operation is described in FIG. 8, and the second type of designated scrub operation is described in FIG. 9.

FIG. 7 is a flowchart for describing a patrol scrub operation according to an embodiment of the present disclosure.

Referring to FIG. 7, a patrol scrub operation (at S160 in FIG. 5) performed on memory cells connected to a specific row is illustrated.

The scrub management module 160 may generate a scrub address ECS_ADD specifying the cells to be scrubbed along with a scrub command ECS_CMD instructing a read operation. At this time, the scrub management module 160 may generate a scrub address ECS_ADD including a row address RA designating the specific row and a column address CA initialized to zero (at S310). The memory device 200 may read data DIO from the memory cells corresponding to the scrub address ECS_ADD (at S320).

If the read data DIO has no error (NE) (“YES” in S330), the scrub management module 160 may increase a value of the column address CA by +1 (at S350). Until the column address CA reaches a maximum value (“NO” in S340), a scrub operation may be performed on the next column address CA. When the column address CA reaches the maximum value (“YES” in S340), the designated scrub process may be finished.

If a correctable error (CE) is detected in the read data DIO (“NO” in S330 & “YES” in S360), the ECC engine 130 may correct an error in the read data DIO (at S362). The scrub management module 160 generates a scrub command ECS_CMD and a scrub address ECS_ADD instructing a write-back operation, and accordingly, the error-corrected data may be written back to the memory cells (at S362). The fault analysis module 150 may increase an error counter based on the error signal ERR provided from the ECC engine 130 (at S364).

At this time, if the correctable error (CE) is a single-bit error or an adjacent two-bit error, or the accumulated error count (#CE) in the currently scrubbed row is below a threshold (e.g., 2) (“NO” in S370), the scrub management module 160 may increase the value of the column address CA by +1 (at S350). Until the column address CA reaches the maximum value (“NO” in S340), a scrub operation may be performed on the next column address CA. When the column address CA reaches the maximum value (“YES” in S340), the designated scrub process may be ended.

On the other hand, if the correctable error (CE) is a multi-bit error (CEm), except for the adjacent two-bit error, or the accumulated error count (#CE) in the currently scrubbed row exceeds the threshold (“YES” in S370), the fault analysis module 150 may generate a faulty row address FADD corresponding to the row address RA, and the scrub control module 160 is requested to perform a first type of a designated scrub operation for the faulty row address FADD (at S380), and the process may be finished.

If an uncorrectable error (UE) is detected in the read data DIO (“NO (UE)” in S360), the ECC engine 130 may poison the read data DIO (at S392). In this case, since the patrol scrub operation is performed independently of the request REQ of the host 20, no notification to the host 20 is provided. The fault analysis module 150 may log the error (at S394) and generate a faulty row address FADD corresponding to the row address RA, then request the scrub control module 160 to perform the first type of the designated scrub operation for the faulty row address FADD (at S380), and the process may be finished.

FIG. 8 is a flowchart for describing a first type of a designated scrub operation according to an embodiment of the present disclosure.

Referring to FIG. 8, a scrub management module 160 may identify adjacent rows to be scrubbed within a fault boundary based on a faulty row corresponding to a faulty row address FADD (at S410). For example, when the sub-word line SWL3 is detected as the faulty row (see FIG. 4A), adjacent rows SWL1 to SWL8, SWL11, SWL19, and SWL27 may be identified to be scrubbed.

First, the scrub operation may be performed on memory cells connected to one (e.g., SWL1) of the identified adjacent rows SWL1 to SWL8, SWL11, SWL19, and SWL27.

The scrub management module 160 may set a row address RA to designate the adjacent row SWL1 and initialize a column address CA to 0 (at S420). The scrub management module 160 may provide a scrub address ECS_ADD including the row address RA and column address CA along with a scrub command ECS_CMD instructing a read operation. The memory device 200 may read data DIO from the memory cells corresponding to the scrub address ECS_ADD according to the scrub command ECS_CMD (at S430). That is, the memory device 200 reads the data DIO from the memory cells connected to a first column of the adjacent row SWL1.

If the read data DIO has no error (NE) (“YES” in S440), the scrub management module 160 may increase a value of the column address CA by +1 (“NO” in S450 & S460).

If a correctable error (CE) is detected in the read data DIO (“NO” in S440 & “YES” in S470), the ECC engine 130 may correct an error in the read data DIO, and the error-corrected data may be written back to the memory cells (at S472). The fault analysis module 150 may increase an error counter based on an error signal ERR from the ECC engine 130 (at S474).

At this time, if the correctable error (CE) is a single-bit error or an adjacent two-bit error, or the accumulated error count (#CE) in the currently scrubbed row is below a threshold (“NO” in S476), the scrub management module 160 may increase the value of the column address CA by +1 (“NO” in S450 & S460).

As the value of the column address CA increases by 1 (at S460), the memory device 200 may read data DIO from memory cells connected to a second column of the adjacent row SWL1 (at S430). Until the column address CA reaches a maximum value (“NO” in S450), the above operations (S440 to S476) may be repeatedly performed for remaining columns of the adjacent row SWL1.

When the column address CA reaches the maximum value (“YES” in S450), the scrub management module 160 may change a value of the row address RA to designate the next adjacent row SWL5 and initialize the column address CA to 0 (“NO” in S492 & S494). Accordingly, the memory device 200 may read data DIO from memory cells connected to a first column of the next adjacent row SWL5 (at S430).

On the other hand, if the correctable error (CE) is a multi-bit error (CEm) except for the adjacent two-bit error, or the accumulated error count (#CE) in the currently scrubbed row exceeds the threshold (“YES” in S476), the fault analysis module 150 may generate a faulty row address FADD corresponding to the adjacent row SWL1 (at S478). Then, the scrub management module 160 may change the value of the row address RA to designate the next adjacent row SWL5 and initialize the column address CA to 0 (“NO” in S492 & S494). Accordingly, the memory device 200 may suspend the scrub operation on the adjacent row SWL1 and read the data DIO from the memory cells connected to the first column of the next adjacent row SWL5 (at S430).

If an uncorrectable error (UE) is detected in the read data DIO (“NO (UE)” in S470), the ECC engine 130 may poison the read data DIO (at S482). In this case, since the designated scrub operation is performed independently of the request REQ of the host 20, no notification to the host 20 is provided. The fault analysis module 150 may log the error (at S484) and generate a faulty row address FADD corresponding to the adjacent row SWL1 (at S478). Then, the scrub management module 160 changes the value of the row address RA to designate the next adjacent row SWL5 and initializes the column address CA to 0 (“NO” in S492 & S494). Accordingly, the memory device 200 may suspend the scrub operation on the adjacent row SWL1 and read the data DIO from the memory cells connected to the first column of the next adjacent row SWL5 (at S430).

Once the designated scrub operation is performed on all identified adjacent rows SWL1 to SWL8, SWL11, SWL19, and SWL27 (“YES” in S492), the process may be finished.

Thereafter, the fault analysis module 150 may generate fault mode information F_MD by analyzing the fault types between the faulty rows based on the detected faulty row addresses FADD as a result of the adaptive scrub operation.

FIG. 9 is a flowchart for describing a second type of a designated scrub operation according to an embodiment of the present disclosure.

Referring to FIG. 9, a scrub management module 160 may identify adjacent rows to be scrubbed within a fault boundary based on a faulty row corresponding to a faulty row address FADD (at S510). For example, when adjacent rows SWL1 to SWL8, SWL11, SWL19, and SWL27 may be identified to be scrubbed, a scrub operation may be performed on memory cells connected to one (e.g., SWL1) of the adjacent rows SWL1 to SWL8, SWL11, SWL19, and SWL27.

The scrub management module 160 may set a row address RA to designate the adjacent row SWL1 and initialize a column address CA to 0 (at S520). The scrub management module 160 may provide a scrub address ECS_ADD including the row address RA and column address CA along with a scrub command ECS_CMD instructing a read operation. The memory device 200 reads data DIO from the memory cells corresponding to the scrub address ECS_ADD according to the scrub command ECS_CMD (at S530). That is, the memory device 200 reads the data DIO from the memory cells connected to a first column of the adjacent row SWL1.

If the read data DIO has no error (NE) (“YES” in S540), the scrub management module 160 may increase a value of the column address CA by +1 (“NO” in S550 & S560).

If a correctable error (CE) is detected in the read data DIO (“NO” in S540 & “YES” in S57), the fault analysis module 150 may increase an error counter based on an error signal ERR provided from the ECC engine 130 (at S572). At this time, since the second type of the designated scrub operation is performed again on data where the uncorrectable error (UE) has already occurred during the demand scrub operation, an error correction operation and a write-back operation may be omitted because they are considered unnecessary.

If the correctable error (CE) is a single-bit error or an adjacent two-bit error, or the accumulated error count (#CE) in the currently scrubbed row is below a threshold (“NO” in S574), the scrub management module 160 may increase the value of the column address CA by +1 (“NO” in S550 & S560).

As the value of the column address CA increases to 1 (at S560), the memory device 200 may read data DIO from memory cells connected to a second column of the adjacent row SWL1 (at S530). Until the column address CA reaches a maximum value (“NO” in S550), the above operations (S540 to S576) may be repeatedly performed for remaining columns of the adjacent row SWL1.

When the column address CA reaches the maximum value (“YES” in S550), the scrub management module 160 may change a value of the row address RA to designate the next adjacent row SWL5 and initialize the column address CA to 0 (“NO” in S592 & S594). Accordingly, the memory device 200 may read data DIO from memory cells connected to a first column of the next adjacent row SWL5 (at S530).

On the other hand, if the correctable error (CE) is a multi-bit error (CEm), except for the adjacent two-bit error, or the accumulated error count (#CE) in the currently scrubbed row exceeds the threshold (“YES” in S574), the fault analysis module 150 may generate a faulty row address FADD corresponding to the adjacent row SWL1 (at S576). Then, the scrub management module 160 may change the value of the row address RA to designate the next adjacent row SWL5 and initialize the column address CA to 0 (“NO” in S592 & S594). Accordingly, the memory device 200 may suspend the scrub operation on the adjacent row SWL1 and read data DIO from memory cells connected to the first column of the next adjacent row SWL5 (at S530).

If an uncorrectable error (UE) is detected in the read data DIO (“NO (UE)” in S570), the fault analysis module 150 may log the error (at S582). Since the second type of the designated scrub operation is performed again on data where the uncorrectable error (UE) has already occurred during the demand scrub operation, the read data DIO is not poisoned. The fault analysis module 150 may generate a faulty row address FADD corresponding to the adjacent row SWL1 (at S576). Then, the scrub management module 160 may change the value of the row address RA to designate the next adjacent row SWL5 and initialize the column address CA to 0 (“NO” in S592 & S594). Accordingly, the memory device 200 may suspend the scrub operation on the adjacent row SWL1 and read data DIO from memory cells connected to the first column of the next adjacent row SWL5 (at S530).

Once the designated scrub operation is performed on all identified adjacent rows SWL1 to SWL8, SWL11, SWL19, and SWL27 (“YES” in S592), a notification operation that is omitted during the demand scrub operation may be performed (at S596). That is, in the second type of the designated scrub operation, the notification operation may be performed to notify that the data is poisoned and has a fatal error before the process is finished, regardless of the generation of the faulty row address FADD. Accordingly, it is possible to improve the reliability of the memory system. Thereafter, the process may be finished.

The fault analysis module 150 may generate fault mode information F_MD by analyzing the fault types between the faulty rows based on the faulty row addresses FADD as a result of the adaptive scrub operation.

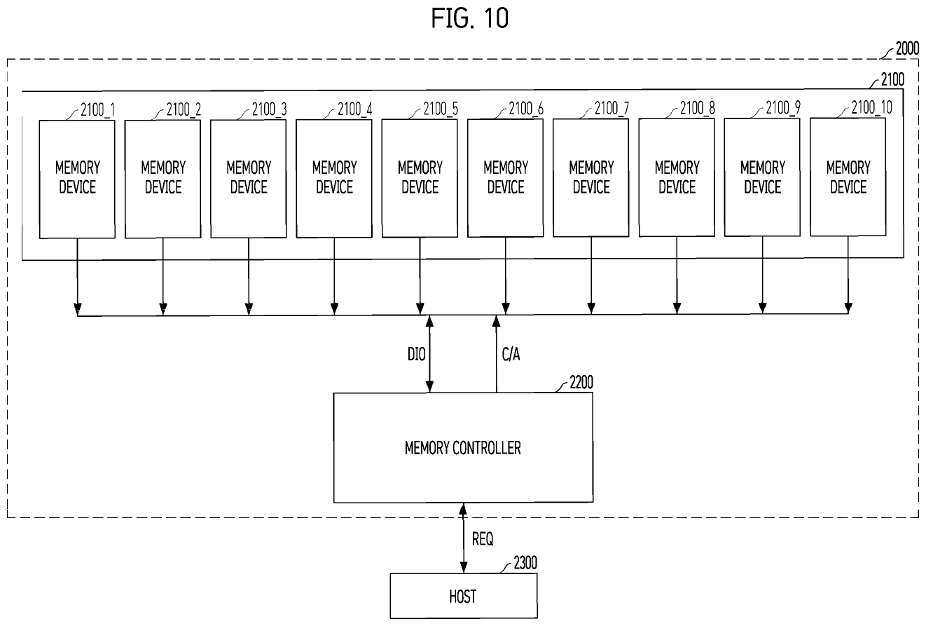

FIG. 10 is a block diagram illustrating a memory system including a memory module according to an embodiment of the present disclosure.

Referring to FIG. 10, a memory system 2000 may include a memory module 2100 and a memory controller 2200.

The memory controller 2200 may control overall operations of the memory system 2000 and control a data transfer between a host 2300 and the memory module 2100. The memory controller 2200 may generate a command/address signal C/A according to a request REQ from the host 2300 to provide the command/address signal C/A to the memory module 2100, and provide data DIO corresponding to the request REQ from the host 2300 to the memory module 2100, and provide data DIO read from the memory module 2100 to the host 2300.

The memory module 2100 may include a plurality of memory devices 2100_1 to 2100_10. In an embodiment, each of the memory devices 2100_1 to 2100_10 may correspond to a memory device 200 described in FIG. 1.

In an embodiment, the memory controller 2200 may correspond to a memory controller 100 described in FIG. 1. The memory controller 2200 may include an error correction code (ECC) engine configured to check and correct an error in data output from the memory device and generate error information; a fault analysis module configured to analyze an error log generated based on the error information to generate and collect a faulty address, and generate fault mode information by analyzing a relationship between collected faulty addresses; and a scrub management module configured to control the memory device to perform a first scrub operation and a second scrub operation, and to control the second scrub operation to be performed on one or more adjacent addresses specified within a fault boundary based on the faulty address generated according to the first scrub operation. As described above, in an embodiment of the present disclosure, when a faulty row is detected as a result of a demand scrub operation or a patrol scrub operation, an additional designated scrub operation may be performed on adjacent rows specified within a fault boundary with reference to the detected faulty row. Accordingly, it is possible to accurately determine the fault types, and to identify errors that have a potential to develop into uncorrectable errors (UEs) according to the fault types, thereby enabling the optimized RAS operation.

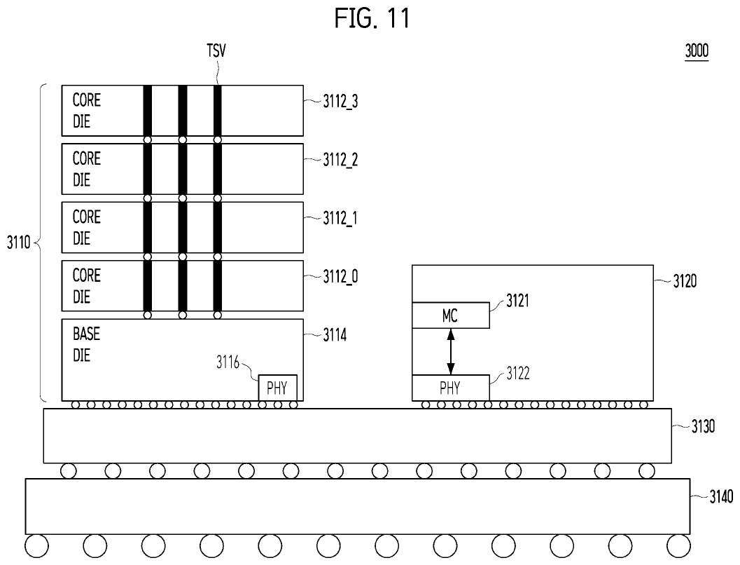

FIG. 11 is a block diagram illustrating a memory system including a stacked memory device according to an embodiment of the present disclosure.

Referring to FIG. 11, a memory system 3000 may include a package substrate 3140, an interposer 3130, a stacked memory device 3110, and a processor 3120.

The package substrate 3140 may include a printed circuit board (PCB). The package substrate 3140 may be electrically connected to an external system board, main board, or module board through bumps.

The interposer 3130 may be formed on the package substrate 3140. The interposer 3130 may be a silicon substrate in which only wiring is formed.

The stacked memory device 3110 and the processor 3120 may be formed on the interposer 3130. The stacked memory device 3110 and the processor 3120 may be disposed on the interposer 3130 spaced apart from each other. Although one stacked memory device 3110 is illustrated in FIG. 11, the embodiments of the present disclosure are not limited thereto, and one or more stacked memory devices may be formed on the interposer 3130 around a processor 3120.

The processor 3120 may include a memory controller (MC) 3121 and a physical interface circuit (PHY) 3122. The memory controller 3121 may be configured to control the stacked memory device 3110. The physical interface circuit 3122 may interface between the memory controller 3121 and the stacked memory device 3110. The physical interface circuit 3122 may be an interface circuit that converts signals transferred from the memory controller 3121 into signals suitable for use in the stacked memory device 3110 and outputs the signals transferred from the stacked memory device 3110 into signals suitable for use in the memory controller 3121. The processor 3120 may be one of various processors such as a micro-processing unit (MPU), a central processing unit (CPU), a general processing unit (GPU), and a host processing unit (HPU).

The stacked memory device 3110 may include a lower chip 3114 and one or more upper chips 3112_0 to 3112_3 vertically stacked on the interposer 3130. An example of the stacked memory device 3110 formed by stacking a plurality of chips as described above may be a high bandwidth memory (HBM). Through electrodes TSV are formed between the lower chip 3114 and the upper chips 3112_0 to 3112_3, through which signals (i.e., commands, addresses, and data) may be transferred between the chips.

The lower chip 3114 may include a physical interface circuit (PHY) 3116 for an interface with the memory controller 3121.

In an embodiment, at least one of the memory controller 3121 and the lower chip 3114 may correspond to a memory controller 100 described in FIG. 1, and each of the upper chips 3112_0 to 3112_3 may correspond to a memory device 200 described in FIG. 1. At least one of the memory controller 3121 and the lower chip 3114 may include an error correction code (ECC) engine configured to check and correct an error in data output from the memory device and generate error information; a fault analysis module configured to analyze an error log generated based on the error information to generate and collect a faulty address, and generate fault mode information by analyzing a relationship between collected faulty addresses; and a scrub management module configured to control the memory device to perform a first scrub operation and a second scrub operation, and to control the second scrub operation to be performed on one or more adjacent addresses specified within a fault boundary based on the faulty address generated according to the first scrub operation. As described above, in an embodiment of the present disclosure, when a faulty row is detected as a result of a demand scrub operation or a patrol scrub operation, an additional designated scrub operation may be performed on adjacent rows specified within a fault boundary with reference to the detected faulty row. Accordingly, it is possible to accurately determine the fault types, and to identify errors that have a potential to develop into uncorrectable errors (UEs) according to the fault types, thereby enabling the optimized RAS operation.

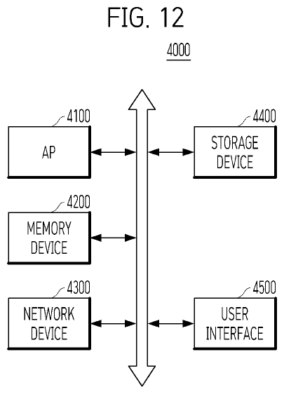

FIG. 12 is a block diagram illustrating a mobile system including a memory device according to an embodiment of the present disclosure.

Referring to FIG. 12 a mobile system 4000 may include an application processor (AP) 4100, a memory device 4200, a network device 4300, a storage device 4400, and a user interface 4500.

The application processor 4100 may drive components, an operating system (OS), or a user program included in the mobile system 4000. For example, the application processor 4100 may be provided as a system-on-chip (SoC).

The memory device 4200 may operate as a main memory, an operation memory, a buffer memory, or a cache memory of the mobile system 4000. The memory device 4200 may include a volatile random access memory such as DRAM, SDRAM, DDR SDRAM, DDR2 SDRAM, DDR3 SDRAM, Low-Power Double Data Rate 3 Synchronous Dynamic Random-Access Memory (LPDDR3 SDRAM), or a nonvolatile random access memory such as phase-change RAM (PRAM), Resistive Random-Access Memory (ReRAM), Magnetoresistive Random-Access Memory (MRAM), Ferroelectric RAM (FRAM), etc. According to an embodiment, the memory device 4200 may be configured as a memory module 2100 described with reference to FIG. 10

The network device 4300 may communicate with external devices. For example, the network device 4300 may support wireless communication such as Code Division Multiple Access (CDMA), Global System for Mobile Communication (GSM), Wideband CDMA (WCDMA), CDMA-2000, Time Division Multiple Access (TDMA), Long Term Evolution (LTE), Worldwide Interoperability for Microwave Access (WiMAX), Wireless Local Area Network (WLAN), Ultra-Wideband (UWB), Bluetooth, Wi-Fi, etc. For example, the network device 4300 may be included in the application processor 4100.

The storage device 4400 may store data. For example, the storage device 4400 may store data received from the application processor 4100. Alternatively, the storage device 4400 may transmit the stored data to the application processor 4100. For example, the storage device 4400 may be implemented as a nonvolatile semiconductor memory device such as a phase-change RAM (PRAM), a magnetic RAM (MRAM), a resistive RAM (RRAM), a NAND flash, a NAND flash, and a three-dimensional NAND flash.

In an embodiment, the application processor 4100 and the memory device 4200 may correspond to a memory controller 100 and a memory device 200, respectively, described in FIG. 1. The application processor 4100 may include an error correction code (ECC) engine configured to check and correct an error in data output from the memory device and generate error information; a fault analysis module configured to analyze an error log generated based on the error information to generate and collect a faulty address, and generate fault mode information by analyzing a relationship between collected faulty addresses; and a scrub management module configured to control the memory device to perform a first scrub operation and a second scrub operation, and to control the second scrub operation to be performed on one or more adjacent addresses specified within a fault boundary based on the faulty address generated according to the first scrub operation. As described above, in an embodiment of the present disclosure, when a faulty row is detected as a result of a demand scrub operation or a patrol scrub operation, an additional designated scrub operation may be performed on adjacent rows specified within a fault boundary with reference to the detected faulty row. Accordingly, it is possible to accurately determine the fault types, and to identify errors that have a potential to develop into uncorrectable errors (UEs) according to the fault types, thereby enabling the optimized RAS operation.

Hereinafter, adaptive scrub operations according to various embodiments of the present disclosure will be described in detail with reference to the drawings.

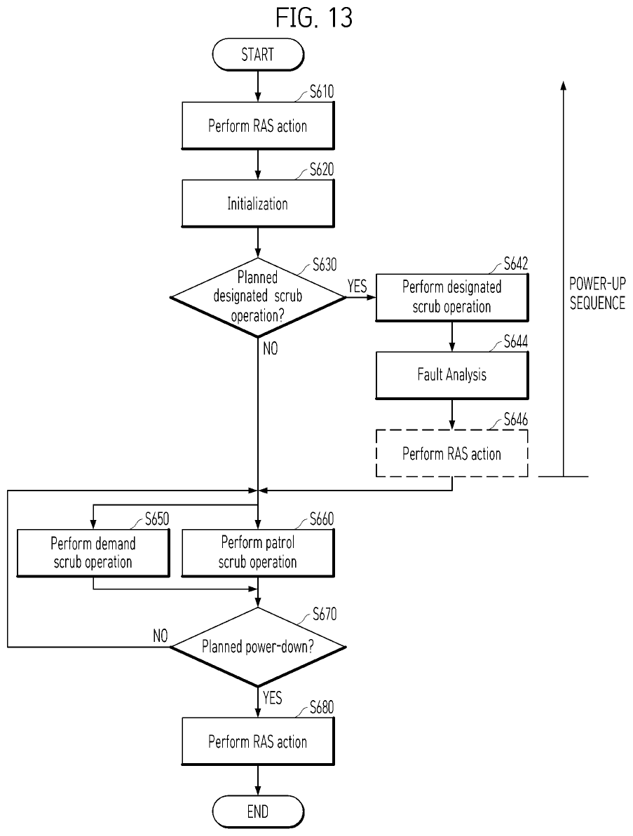

FIG. 13 is a flowchart for describing an adaptive scrub operation according to another embodiment of the present disclosure.

Referring to FIG. 13, first, upon power-up, the memory system 10 may perform a reliability, availability, and serviceability (RAS) operation to improve the reliability of the memory device 200 (at S610). For example, the memory system 10 may perform a post-package repair operation, a page offlining operation, a row remapping operation, a bank spare/migration operation, etc.

The memory system 10 may perform an initialization operation (at S620). During the initialization operation, the memory system 10 may execute an initialization sequence defined in the Joint Electron Device Engineering Council (JEDEC) standard. For example, the memory system 10 may perform an internal circuit initialization operation such as internal voltage level stabilization and clock locking operations for the memory controller 100 and the memory device 200. In addition, the memory system 10 may perform an initialization operation such as mode register set (MRS) configuration, ZQ calibration, and impedance matching of the memory device 200. Depending on the embodiment, the RAS operation (at S610) may be performed during the initialization operation (at S620).

Thereafter, the scrub management module 160 of the memory controller 100 may determine whether a planned (or scheduled) designated scrub operation exists (at S630). The scrub management module 160 of the memory controller 100 may determine whether a planned designated scrub operation exists by checking whether a faulty row address FADD, detected by a previous demand scrub operation or patrol scrub operation, is stored in a non-volatile memory (at S630). For reference, when the faulty row address FADD is stored in the non-volatile memory, the scrub management module 160 may determine that a planned designated scrub operation exists.

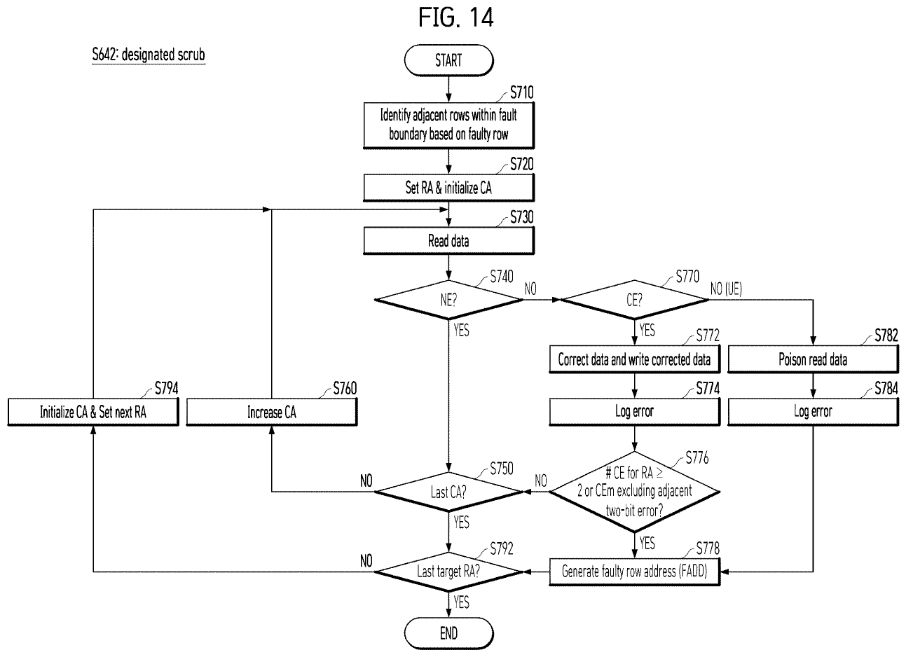

When the planned designated scrub operation exists (“YES” in S630), the scrub management module 160 may perform the designated scrub operation on the faulty row address FADD (at S642). The scrub management module 160 may set a fault boundary and generate a scrub command ECS_CMD and a scrub address ECS_ADD as many times as needed to check for errors in memory cells connected to adjacent rows specified within the fault boundary based on the faulty row. For example, as shown in FIG. 4A, when a faulty row address FADD for a sub-word line SWL3 is stored, the scrub management module 160 may generate a scrub command ECS_CMD and a scrub address ECS_ADD to perform the designated scrub operation on adjacent rows, e.g., SWL1 to SWL8, SWL11, SWL19, and SWL27 arranged in two cell groups adjacent in the column direction, as shown in FIGS. 4B to 4E. Meanwhile, the designated scrub operation will be described in FIG. 14.

The fault analysis module 150 may generate the fault mode information F_MD by analyzing fault types among detected faulty rows according to the result of performing the designated scrub operation (at S644).

After the planned designated scrub operation (at S642) and the fault analysis (at S644) are completed, the RAS manager 122 may selectively perform a RAS operation to improve the reliability of the memory device 200 based on the fault mode information F_MD (at S646). For example, the RAS manager 122 may control the system to perform a post-package repair operation, a page offlining operation, a row remapping operation, a bank spare/migration operation, etc. Meanwhile, the RAS operation (at S646) may be performed during run-time depending on product specifications, and may be omitted if it is difficult to perform during run-time. In FIG. 13, the RAS operation (at S646) is indicated by a dotted line to show that it is optional.

Thereafter, the memory system 10 may perform a normal operation, such as a read operation or a write operation, according to a request REQ from the host 20. For reference, operations from power-up until before the normal operation is performed (from S610 to S646) may be referred to as a power-up sequence operation.

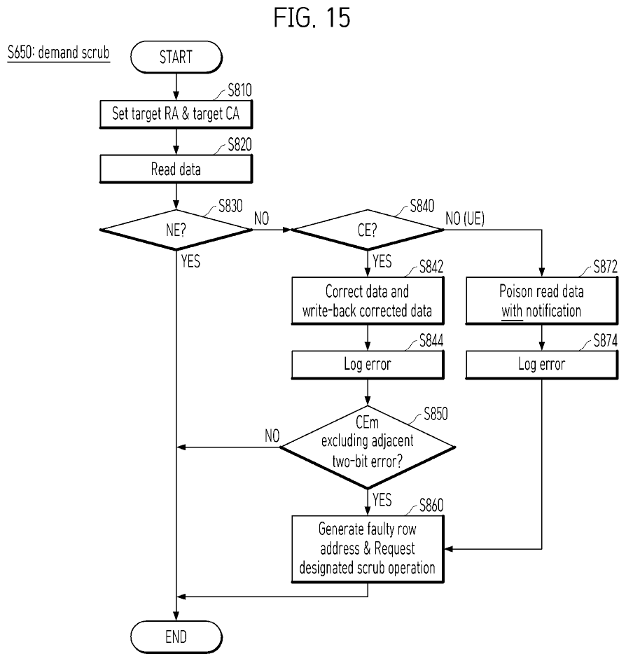

The scrub management module 160 may perform a demand scrub operation on data DIO read from the target memory cells of the memory device 200 during a read operation (at S650). The ECC engine 130 may check an error in the data DIO read from the target memory cells, generate an error signal ERR, and generate error-corrected data by correcting the error in the data DIO. The error-corrected data may be provided to the host 20 through the host interface 110. At this time, the scrub management module 160 may perform the demand scrub operation by writing back the error-corrected data to the target memory cells. The demand scrub operation will be described in FIG. 15. The fault analysis module 150 may generate a row address for specifying target memory cells as a faulty row address FADD according to the error signal ERR occurring during the error check operation for the data DIO read from the target memory cells.

Meanwhile, the scrub management module 160 may perform a patrol scrub operation for all memory cells of the memory device 200 over a predetermined intervals (e.g., every 24 hours) (at S660). The scrub management module 160 may perform a scrub operation for each row, including a read operation for reading data from memory cells, an error check operation for checking and correcting an error in the read data, and a write-back operation for writing the error-corrected data back to the memory device 200. The fault analysis module 150 may generate a faulty row address FADD corresponding to a respective row according to the error signal ERR occurring for each row during the patrol scrub operation.

The fault analysis module 150 may provide the faulty row address FADD generated by the demand scrub operation or the patrol scrub operation, to the scrub management module 160. The scrub management module 160 may store the faulty row address FADD in the non-volatile memory. Since the faulty row address FADD is stored in the non-volatile memory even if the memory system 10 is powered down or powered off, the scrub management module 160 may determine whether the planned designated scrub operation exists based on the faulty row address FADD stored in the non-volatile memory after power-up.

Until a planned power-down occurs (“NO” in S670), the demand scrub operation (at S650) or the patrol scrub operation (at S660) may be repeatedly performed.

When a planned power-down is requested from the host 20 (“YES” in S670), the RAS manager 122 may perform a RAS operation according to the fault mode information F_MD (at S680). Accordingly, the operation of the memory system 10 may be completed.

Meanwhile, depending on product specifications, only one of the demand scrub operation and the patrol scrub operation may be performed instead of both. For example, in the case of a product where only the demand scrub operation is requested, if a faulty row is detected as a result of the demand scrub operation, an additional designated scrub operation may be performed on adjacent rows specified within a fault boundary based on the detected faulty row. Alternatively, in the case of a product where only the patrol scrub operation is requested, if a faulty row is detected as a result of the patrol scrub operation, an additional designated scrub operation may be performed on adjacent rows specified within a fault boundary based on the detected faulty row.

As described above, in an embodiment of the present disclosure, when a faulty row is detected as a result of a demand scrub operation or a patrol scrub operation, an additional designated scrub operation may be performed during a power-up sequence operation on adjacent rows specified within a fault boundary based on the detected faulty row. Therefore, it is possible to provide an optimized RAS operation by detecting accurate fault types and discovering errors with a potential to develop into UEs that were not previously detected according to the detected fault types.

FIG. 14 is a flowchart for describing the designated scrub operation (at S642) of FIG. 13 in more detail.

Referring to FIG. 14, the scrub management module 160 may check adjacent rows to be scrubbed within a fault boundary based on a faulty row corresponding to a faulty row address FADD (at S710). For example, when a sub-word line SWL3 is detected as a faulty row (FIG. 4A), the scrub management module 160 may specify adjacent rows SWL1 to SWL8, SWL11, SWL19, and SWL27 to be scrubbed.

First, a scrub operation may be performed on memory cells connected to one adjacent row SWL1 among the specified adjacent rows SWL1 to SWL8, SWL11, SWL19, and SWL27. The scrub management module 160 may set a row address RA to designate the adjacent row SWL1 and initialize a column address CA to 0 (at S720). The scrub management module 160 may provide a scrub address ECS_ADD including the row address RA and the column address CA along with a scrub command ECS_CMD instructing a read operation. The memory device 200 may read data DIO from memory cells corresponding to the scrub address ECS_ADD according to the scrub command ECS_CMD (at S730). That is, the memory device 200 may read the data DIO from the memory cells connected to a first column of the adjacent row SWL1.

If the read data DIO has no error (NE) (“YES” in S740), the scrub management module 160 may increase a value of the column address CA by +1 (“NO” in S750 & S760).

If a correctable error (CE) is detected in the read data DIO (“NO” in S740 & “YES” in S770), the ECC engine 130 may correct an error of the read data DIO, and the error-corrected data may be written back to the memory cells (at S772). The fault analysis module 150 may increase an error counter according to an error signal ERR provided from the ECC engine 130 (at S774).

At this time, when the correctable error (CE) is a single-bit error or an adjacent 2-bit error, or an accumulated error count (#CE) in the currently scrubbed row is less than a threshold (“NO” in S776), the scrub management module 160 may increase the value of the column address CA by +1 (“NO” in S750 & S760).

As the value of the column address CA is increased to 1 (at S760), the memory device 200 may read data DIO from memory cells connected to a second column of the adjacent row SWL1 (at S730). Until the value of the column address CA reaches a maximum value (“NO” in S750), the above operations (S740 to S776) may be performed for all columns of the adjacent row SWL1.

Thereafter, when the value of the column address CA reaches the maximum value (“YES” in S750), the scrub management module 160 may change the row address RA to designate the next adjacent row SWL5 and initialize the value of the column address CA to 0 (“NO” in S792 & S794). Accordingly, the memory device 200 may read data DIO from memory cells connected to a first column of the next adjacent row SWL5 (at S730).

On the other hand, when the correctable error (CE) is a multi-bit error (CEm) except for an adjacent 2-bit error, or an accumulated error count (#CE) in the currently scrubbed row is equal to or greater than the threshold (“YES” in S776), the fault analysis module 150 may generate a faulty row address FADD corresponding to the adjacent row SWL1 (at S778). Thereafter, the scrub management module 160 may change the row address RA to designate the next adjacent row SWL5 and initialize the value of the column address CA to 0 (“NO” in S792 & S794). Accordingly, the memory device 200 may stop the scrub operation for the adjacent row SWL1 and read data DIO from memory cells connected to the first column of the next adjacent row SWL5 (at S730).

If an uncorrectable error (UE) is detected in the read data DIO (“NO(UE)” in S770), the ECC engine 130 may poison the read data DIO (at S782). In this case, since the designated scrub operation is an operation performed independently of the request REQ from the host 20, no notification to the host 20 is provided. The fault analysis module 150 may log the error (at S784) and generate a faulty row address FADD corresponding to the adjacent row SWL1 (at S778). Thereafter, the scrub management module 160 may change the row address RA to designate the next adjacent row SWL5 and initialize the value of the column address CA to 0 (“NO” in S792 & S794). Accordingly, the memory device 200 may stop the scrub operation for the adjacent row SWL1 and read data DIO from memory cells connected to the first column of the next adjacent row SWL5 (at S730).

When the scrub operation is performed for all identified adjacent rows SWL1 to SWL8, SWL11, SWL19, and SWL27 (“YES” in S792), the process may be terminated.

Thereafter, the fault analysis module 150 may generate fault mode information F_MD by analyzing the fault types between the faulty rows based on the detected faulty row addresses FADD as a result of the adaptive scrub operation.

FIG. 15 is a flowchart for describing the demand scrub operation (at S650) of FIG. 13 in more detail.

Referring to FIG. 15, the demand scrub operation (at S650) performed during a read operation is shown.

During a read operation, the command/address handler 124 may set a row address and a column address to designate target memory cells according to the request REQ from the host 20 (at S810). Hereinafter, the row address and the column address for specifying the target memory cells will be referred to as a target row address RA and a target column address CA, respectively. The memory device 200 may read data DIO from target memory cells corresponding to the target row address RA and the target column address CA (at S820).

If the read data DIO has no error (NE) (“YES” in S830), the read data DIO is provided to the host 20, and the process may be terminated.

If a correctable error (CE) is detected in the read data DIO (“NO” in S830 & “YES” in S840), the ECC engine 130 may correct an error of the read data DIO. The scrub management module 160 may generate a scrub command ECS_CMD and a scrub address ECS_ADD instructing a write-back operation, and accordingly, the error-corrected data may be written to the target memory cells (at S842). The fault analysis module 150 may log the error based on an error signal ERR provided from the ECC engine 130 (at S844).

If the correctable error (CE) is a single-bit error or an adjacent 2-bit error (“NO” in S850), the process may be terminated. On the other hand, if the correctable error (CE) is a multi-bit error (CEm) except for an adjacent 2-bit error (“YES” in S850), the fault analysis module 150 may generate a faulty row address FADD corresponding to the target row address RA and request a designated scrub operation for the faulty row address FADD from the scrub control module 160 (at S860).

If an uncorrectable error (UE) is detected in the read data DIO (“NO(UE)” in S840), the ECC engine 130 may poison the read data DIO and may improve reliability by notifying the host 20 that the corresponding data is poison data (at S872). The fault analysis module 150 may log the error according to the error signal ERR provided from the ECC engine 130 (at S874). The fault analysis module 150 may generate a faulty row address FADD corresponding to the target row address RA and request a designated scrub operation for the faulty row address FADD from the scrub control module 160 (at S860).

For reference, the patrol scrub operation (at S660) performed for each row in FIG. 13 will be described with reference to FIG. 7.

Referring to FIG. 7, the patrol scrub operation (at S660) performed on memory cells connected to any one row is shown.

The scrub management module 160 may generate a scrub address ECS_ADD specifying memory cells to be scrubbed along with a scrub command ECS_CMD instructing a read operation. At this time, the scrub management module 160 may generate a scrub address ECS_ADD including a row address RA specifying any one row and a column address CA initialized to a value of 0 (at S310). The memory device 200 may read data DIO from memory cells corresponding to the scrub address ECS_ADD (at S320).

If the read data DIO has no error (NE) (“YES” in S330), the scrub management module 160 may increase the value of the column address CA by +1 (at S350). Until the value of the column address CA reaches a maximum value (“NO” in S340), the scrub operation may be performed for the next column address CA. When the value of the column address CA reaches the maximum value (“YES” in S340), the process may be terminated.

If a correctable error (CE) is detected in the read data DIO (“NO” in S330 & “YES” in S360), the ECC engine 130 may correct an error of the read data DIO (at S362). The scrub management module 160 may generate a scrub command ECS_CMD and a scrub address ECS_ADD instructing a write-back operation, and accordingly, the error-corrected data may be written to the memory cells (at S362). The fault analysis module 150 may increase an error counter according to an error signal ERR provided from the ECC engine 130 (at S364).

At this time, if the correctable error (CE) is a single-bit error or an adjacent 2-bit error, or an accumulated error count (#CE) occurring in the currently scrubbed row is less than a threshold (e.g., 2) (“NO” in S370), the scrub management module 160 may increase the value of the column address CA by +1 (at S350). Until the value of the column address CA reaches the maximum value (“NO” in S340), a scrub operation may be performed on the next column address CA. When the value of the column address CA reaches the maximum value (“YES” in S340), the process may be terminated.

On the other hand, if the correctable error (CE) is a multi-bit error (CEm) except for an adjacent 2-bit error, or an accumulated error count (#CE) in the currently scrubbed row is equal to or greater than the threshold (“YES” in S370), the fault analysis module 150 may generate a faulty row address FADD corresponding to the row address RA and request a designated scrub operation for the faulty row address FADD from the scrub control module 160 (at S380). Accordingly, the process may be terminated.

If an uncorrectable error (UE) is detected in the read data DIO (“NO(UE)” in S360), the ECC engine 130 may poison the read data DIO (at S392). In this case, since the patrol scrub operation is performed independently of the request REQ of the host 20, no notification to the host 20 is provided. The fault analysis module 150 may log the error (at S394) and generate a faulty row address FADD corresponding to the row address RA and request a designated scrub operation for the faulty row address FADD from the scrub control module 160 (at S380). Accordingly, the process may be terminated.

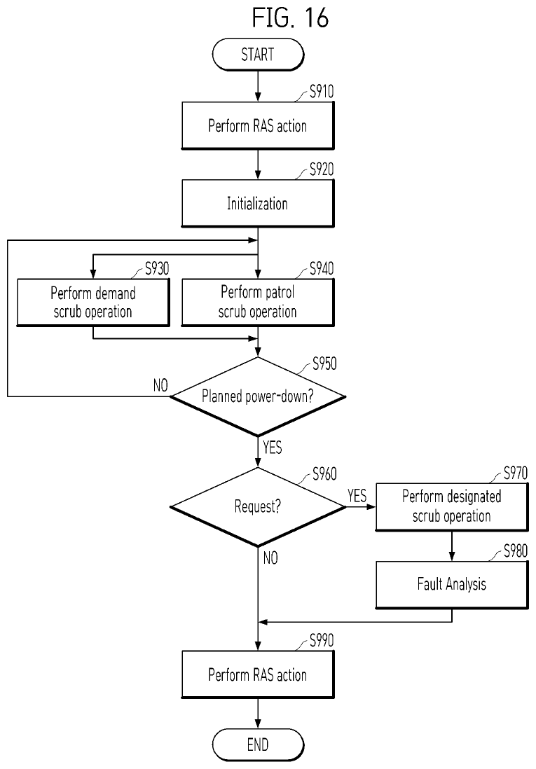

FIG. 16 is a flowchart for describing an adaptive scrub operation according to another embodiment of the present disclosure.

Referring to FIG. 16, first, upon power-up, the memory system 10 may perform a RAS operation to improve the reliability of the memory device 200 (at S910). The memory system 10 may perform an initialization operation (at S920). During the initialization operation, the memory system 10 may execute an initialization sequence defined in the JEDEC standard. Meanwhile, in FIG. 16, the RAS operation (at S910) and the initialization operation (at S920) are described as separate operations, but depending on the embodiment, the RAS operation (at S910) may be performed during the initialization operation (at S920).

Thereafter, the memory system 10 may perform a normal operation such as a read operation or a write operation according to a request REQ from the host 20.

The scrub management module 160 may perform a demand scrub operation on data DIO read from target memory cells of the memory device 200 during a read operation (at S930). The ECC engine 130 may check an error in the data DIO read from the target memory cells, generate an error signal ERR, and generate error-corrected data by correcting the error in the data DIO. The error-corrected data may be provided to the host 20 through the host interface 110. At this time, the scrub management module 160 may perform the demand scrub operation by writing back the error-corrected data to the target memory cells. The demand scrub operation (at S930) of FIG. 16 is substantially the same as the demand scrub operation (at S650) of FIG. 13 and may be performed by substantially the same processes as described in FIG. 15. The fault analysis module 150 may generate a row address specifying target memory cells as a faulty row address FADD according to the error signal ERR occurring during the error check operation for the data DIO read from the target memory cells.

Meanwhile, the scrub management module 160 may perform a patrol scrub operation for all memory cells of the memory device 200 over a predetermined intervals (e.g., every 24 hours) (at S940). The scrub management module 160 may perform a scrub operation for each row, including a read operation for reading data from memory cells, an error check operation for checking and correcting an error in the read data, and a write-back operation for writing the error-corrected data back to the memory device 200. The patrol scrub operation (at S940) of FIG. 16 is substantially the same as the patrol scrub operation (at S660) of FIG. 13 and may be performed by substantially the same processes as described in FIG. 7. The fault analysis module 150 may generate a faulty row address FADD corresponding to a respective row according to the error signal ERR occurring for each row during the patrol scrub operation.

Until a planned power-down occurs (“NO” in S950), the demand scrub operation (at S930) or the patrol scrub operation (at S940) may be repeatedly performed.

When a planned power-down is requested from the host 20 (“YES” in S950), the scrub management module 160 may check whether a designated scrub operation is requested (at S960) according to a faulty row address FADD detected according to the demand scrub operation (at S930) or the patrol scrub operation (at S940). When a detected faulty row address FADD exists, the scrub management module 160 may determine that the designated scrub operation is requested.

When the designated scrub operation is not requested (“NO” in S960), the RAS manager 122 may perform a RAS operation to improve the reliability of the memory device 200 according to previously stored fault mode information F_MD (at S990).

On the other hand, when the designated scrub operation is requested (“YES” in S960), the scrub management module 160 may perform a designated scrub operation for the detected faulty row address FADD (at S970), and the fault analysis module 150 may generate fault mode information F_MD by analyzing fault types among detected faulty rows according to the result of performing the designated scrub operation (at S980). Thereafter, the RAS manager 122 may perform a RAS operation according to the fault mode information F_MD (at S990). Accordingly, the operation of the memory system 10 may be completed. Meanwhile, depending on product specifications, only one of the demand scrub operation and the patrol scrub operation may be performed instead of both.

Thereafter, the control module 120 may power down the memory device 200 according to the planned power-down request.

As described above, in an embodiment of the present disclosure, when a faulty row is detected as a result of a demand scrub operation or a patrol scrub operation, an additional designated scrub operation may be performed after a planned power-down is requested on adjacent rows specified within a fault boundary based on the detected faulty row. Therefore, it is possible to provide an optimized RAS operation by detecting accurate fault types and discovering errors with a potential to develop into UEs that were not previously detected according to the detected fault types.

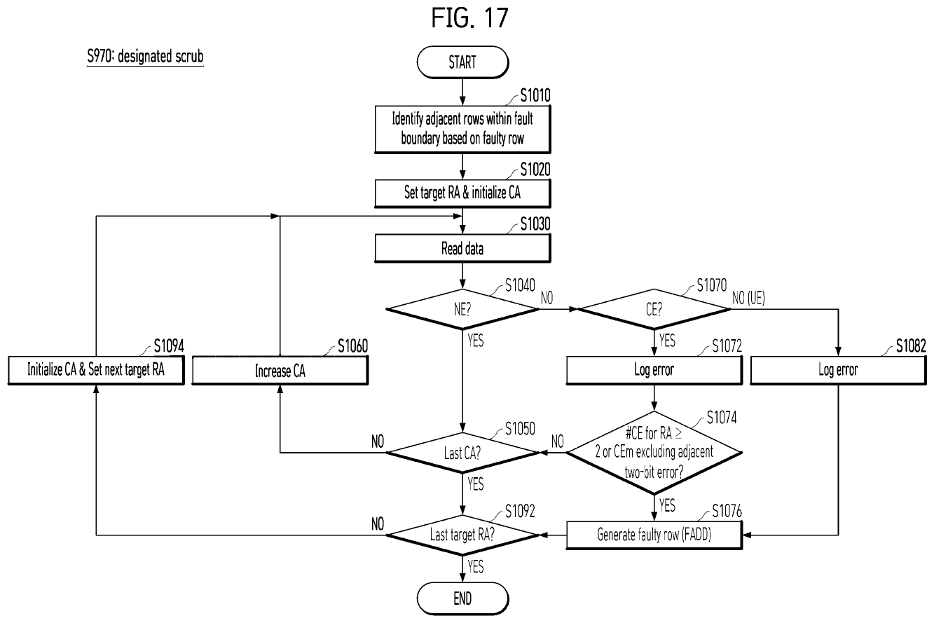

FIG. 17 is a flowchart for describing the designated scrub operation (at S970) of FIG. 16 in more detail.

Referring to FIG. 17, the scrub management module 160 may check adjacent rows to be scrubbed within a fault boundary based on a faulty row corresponding to a faulty row address FADD (at S1010). For example, a scrub operation may be performed on memory cells connected to one adjacent row SWL1 among adjacent rows SWL1 to SWL8, SWL11, SWL19, and SWL27 to be scrubbed.

The scrub management module 160 may set a row address RA to specify the adjacent row SWL1 and initialize a column address CA to 0 (at S1020). The scrub management module 160 may provide a scrub address ECS_ADD including the row address RA and the column address CA along with a scrub command ECS_CMD instructing a read operation. The memory device 200 may read data DIO from memory cells corresponding to the scrub address ECS_ADD according to the scrub command ECS_CMD (at S1030). That is, the memory device 200 may read the data DIO from memory cells connected to a first column of the adjacent row SWL1.

If the read data DIO has no error (NE) (“YES” in S1040), the scrub management module 160 may increase a value of the column address CA by +1 (“NO” in S1050 & S1060).

If a correctable error (CE) is detected in the read data DIO (“NO” in S1040 & “YES” in S1070), the fault analysis module 150 may increase an error counter according to an error signal ERR provided from the ECC engine 130 (at S1072). At this time, since the designated scrub operation is an operation performed once more for data where an uncorrectable error (UE) has already occurred during the demand scrub operation, it is determined that error correction and write-back operations are unnecessary and may be omitted.

When the correctable error (CE) is a single-bit error or an adjacent 2-bit error, or an accumulated error count (#CE) in the currently scrubbed row is less than a threshold (“NO” in S1074), the scrub management module 160 may increase the value of the column address CA by +1 (“NO” in S1050 & S1060).

As the value of the column address CA is increased to 1 (at S1060), the memory device 200 may read data DIO from memory cells connected to a second column of the adjacent row SWL1 (at S1030). Until the value of the column address CA reaches a maximum value (“NO” in S1050), the above operations (S1040 to S1076) may be performed for all columns of the adjacent row SWL1.

Thereafter, when the value of the column address CA reaches the maximum value (“YES” in S1050), the scrub management module 160 may change the row address RA to specify the next adjacent row SWL5 and initialize the value of the column address CA to 0 (“NO” in S1092 & S1094). Accordingly, the memory device 200 may read data DIO from memory cells connected to a first column of the next adjacent row SWL5 (at S1030).

On the other hand, when the correctable error (CE) is a multi-bit error (CEm) except for an adjacent 2-bit error, or an accumulated error count (#CE) in the currently scrubbed row is equal to or greater than the threshold (“YES” in S1074), the fault analysis module 150 may generate a faulty row address FADD corresponding to the adjacent row SWL1 (at S1076). Thereafter, the scrub management module 160 may change the row address RA to specify the next adjacent row SWL5 and initialize the value of the column address CA to 0 (“NO” in S1092 & S1094). Accordingly, the memory device 200 may stop the scrub operation for the adjacent row SWL1 and read data DIO from memory cells connected to the first column of the next adjacent row SWL5 (at S1030).

If an uncorrectable error (UE) is detected in the read data DIO (“NO(UE)” in S1070), the fault analysis module 150 may log the error (at S1082). At this time, since the designated scrub operation is an operation performed once more for data where the UE has already occurred during the demand scrub operation, an operation of poisoning the read data DIO is not performed. The fault analysis module 150 may generate a faulty row address FADD corresponding to the adjacent row SWL1 (at S1076). Thereafter, the scrub management module 160 may change the row address RA to specify the next adjacent row SWL5 and initialize the value of the column address CA to 0 (“NO” in S1092 & S1094). Accordingly, the memory device 200 may stop the scrub operation for the adjacent row SWL1 and read data DIO from memory cells connected to the first column of the next adjacent row SWL5 (at S1030).

When the designated scrub operation is performed for all identified adjacent rows SWL1 to SWL8, SWL11, SWL19, and SWL27 (“YES” in S1092), the process may be terminated.

Thereafter, the fault analysis module 150 may generate fault mode information F_MD by analyzing the fault types between the faulty rows based on the detected faulty row addresses FADD as a result of the adaptive scrub operation.

While the present disclosure has been described with respect to the specific embodiments, it will be apparent to those skilled in the art that various changes and modifications may be made without departing from the spirit and scope of the disclosure as defined in the following claims. Furthermore, the embodiments may be combined to form additional embodiments.

What is claimed is:

1. An operating method of a controller, comprising:
performing a second scrub operation on one or more adjacent rows specified within a fault boundary based on a faulty row corresponding to a faulty address stored in a non-volatile memory during a power-up sequence operation; and
after the power-up sequence operation, storing an address of a target row in the non-volatile memory according to a result of performing a first scrub operation on the target row among a plurality of rows of a memory device.

2. The operating method of claim 1, further comprising:
sharing sub-word line drivers in a row direction and sharing bit line sense amplifiers in a column direction when the memory device includes a plurality of cell blocks that are arranged in an array in the row direction and the column direction,
setting the fault boundary including an n (n is an integer greater than or equal to 2) number of cell groups that are adjacent in the column direction, each cell group formed by cell blocks arranged in the row direction, from among the plurality of cell blocks.

3. The operating method of claim 1, wherein the first scrub operation includes:
reading data from target memory cells specified by the target row and a target column among a plurality of columns according to a request from a host during a read operation;
when an error of the read data is a correctable multi-bit error except for an adjacent 2-bit error, storing the address of the target row in the non-volatile memory; and
when the error is an uncorrectable error, storing the address of the target row in the non-volatile memory.

4. The operating method of claim 3, wherein the first scrub operation further includes:
when the error is the uncorrectable error, poisoning the read data and notifying the host that the read data is poison data.

5. The operating method of claim 1, wherein the first scrub operation includes:
sequentially reading data from memory cells connected to the target row;
when an error of the read data is a correctable multi-bit error except for an adjacent 2-bit error or an accumulated error count of the target row is equal to or greater than a threshold, storing the address of the target row in the non-volatile memory; and
when the error is an uncorrectable error, storing the address of the target row in the non-volatile memory.

6. The operating method of claim 1, wherein the second scrub operation includes:
identifying the one or more adjacent rows within the fault boundary based on the faulty row; and
repeatedly performing an operation for the one or more adjacent rows, the operation including sequentially reading data from memory cells connected to a selected adjacent row, determining the selected adjacent row as a faulty adjacent row when an error of the read data is a correctable multi-bit error except for an adjacent 2-bit error or an accumulated error count of the selected adjacent row is equal to or greater than a threshold, or when the error is an uncorrectable error.

7. The operating method of claim 6, wherein the second scrub operation further includes:
when the error of the read data is a correctable error, correcting the read data and writing back the error-corrected data to the memory cells; and
when the error is the uncorrectable error, poisoning the read data.

8. The operating method of claim 1, further comprising:
determining whether the one or more adjacent rows are faulty adjacent rows according to the second scrub operation; and
generating fault mode information by analyzing a relationship between the faulty row and the faulty adjacent rows.

9. The operating method of claim 8, further comprising:
performing an operation of instructing the memory device or requesting a host to perform an operation for improving reliability of the memory device according to the fault mode information.

10. An operating method of a controller, comprising:
determining whether a target row among a plurality of rows of a memory device is a faulty row according to a result of performing a first scrub operation on the target row;
receiving a scheduled power-down request from a host; and
in response to the scheduled power-down request, performing a second scrub operation on one or more adjacent rows specified within a fault boundary based on the faulty row.

11. The operating method of claim 10, further comprising:
sharing sub-word line drivers in a row direction and sharing bit line sense amplifiers in a column direction when the memory device includes a plurality of cell blocks that are arranged in an array in the row direction and the column direction,
setting the fault boundary including an n (n is an integer greater than or equal to 2) number of cell groups that are adjacent in the column direction, each cell group formed by cell blocks arranged in the row direction, from among the plurality of cell blocks.

12. The operating method of claim 10, wherein the first scrub operation includes:
reading data from target memory cells specified by the target row and a target column among a plurality of columns according to a request from the host during a read operation;
when an error of the read data is a correctable multi-bit error except for an adjacent 2-bit error, determining the target row as the faulty row; and
when the error is an uncorrectable error, determining the target row as the faulty row.

13. The operating method of claim 12, wherein the first scrub operation further includes:
when the error is the uncorrectable error, poisoning the read data and notifying the host that the read data is poison data.

14. The operating method of claim 10, wherein the first scrub operation includes:
sequentially reading data from memory cells connected to the target row;
when an error of the read data is a correctable multi-bit error except for an adjacent 2-bit error or an accumulated error count of the target row is equal to or greater than a threshold, determining the target row as the faulty row; and
when the error of the read data is an uncorrectable error, determining the target row as the faulty row.

15. The operating method of claim 10, wherein the second scrub operation includes:
identifying the one or more adjacent rows within the fault boundary based on the faulty row; and
repeatedly performing an operation for the one or more adjacent rows, the operation including sequentially reading data from memory cells connected to a selected adjacent row, determining the selected adjacent row as a faulty adjacent row when an error of the read data is a correctable multi-bit error except for an adjacent 2-bit error or an accumulated error count of the selected adjacent row is equal to or greater than a threshold, or when the error is an uncorrectable error.

16. The operating method of claim 10, further comprising:
determining whether the one or more adjacent rows are faulty adjacent rows according to the second scrub operation;
generating fault mode information by analyzing a relationship between the faulty row and the faulty adjacent rows; and
powering down the memory device.

17. The operating method of claim 16, further comprising:
performing an operation of instructing the memory device or requesting the host to perform an operation for improving reliability of the memory device according to the fault mode information.
